(19) United States
(12) Patent Application Publication
(10) Pub. No.: US 2025/0314615 A1
(43) Pub. Date: Oct. 9, 2025

(54) VERTICAL TRANSISTOR DUAL GATE BIOSENSOR

(71) Applicant: International Business Machines Corporation, Armonk, NY (US)

(72) Inventors: Jeremy R. Fox, Georgetown, TX (US); Martin G. Keen, Cary, NC (US); Alexander Reznicek, Troy, NY (US); Bahman Hekmatshoartabari, White Plains, NY (US)

(21) Appl. No.: 18/628,869

(22) Filed: Apr. 8, 2024

(51) Int. Cl. G01N 27/414; H01L 27/092; H01L 29/66; H01L 29/78

(52) U.S. Cl. CPC G01N 27/4148; H10D 30/025; H10D 30/63; H10D 84/85

(57) ABSTRACT

Embodiments relate to a vertical transistor dual gate biosensor. A technique includes forming a first vertical field-effect transistor (VFET) having a first gate and forming a second VFET having a second gate. The first and second gates include a shared trench formed in between the first VFET and the second VFET, where the first gate includes a first sidewall of the shared trench, and where the second gate includes a second sidewall of the shared trench. The first sidewall is opposite the second sidewall in the shared trench.

### BACKGROUND

The present invention generally relates to fabrication methods and resulting structures for integrated circuits, and more specifically, to fabrication methods and resulting structures configured and arranged for a vertical transistor dual gate biosensor.

A metal-oxide-semiconductor field-effect transistor (MOSFET) is a transistor used for amplifying or switching electronic signals. The MOSFET has a source, a drain, and a metal oxide gate electrode. The metal gate is electrically insulated from the main semiconductor n-channel or p-channel by a thin layer of insulating material, for example, silicon dioxide or glass, which makes the input resistance of the MOSFET relatively high. The gate voltage controls whether the current path from the source to the drain is an open circuit (“off”) or a resistive path (“on”). N-type field effect transistors (NFET) and p-type field effect transistors (PFET) are two types of complementary MOSFETs. The NFET includes n-doped source and drain junctions and uses electrons as the current carriers. The PFET includes p-doped source and drain junctions and uses holes as the current carriers.

One type of MOSFET is a non-planar FET known generally as a vertical transport FET (VTFET). VTFETs employ semiconductor fins and side-gates that can be contacted outside the active region, resulting in increased device density and some increased performance over lateral devices. In VTFETs, the source to drain current flows in a direction that is perpendicular to a major surface of the substrate. For example, in a known VTFET configuration, a major substrate surface is horizontal and a vertical fin extends upward from the substrate surface. The fin forms the channel region of the transistor. A source region and a drain region are situated in electrical contact with the top and bottom ends of the channel region, while a gate is disposed on one or more of the fin sidewalls.

The threshold voltage (Vt) of a transistor is the voltage level that must be achieved between the gate and the source in order to turn the transistor on. More specifically, when a voltage greater than Vt is applied to the transistor gate, the transistor is turned on, and current flows from the transistor's source through the channel to the drain. When the voltage at the gate is less than Vt, the switch is off, and current does not flow through the transistor.

### SUMMARY

Embodiments of the present invention are directed to methods for a vertical transistor dual gate biosensor. A non-limiting example method includes forming a first vertical field-effect transistor (VFET) having a first gate and forming a second VFET having a second gate. The first and second gates include a shared trench formed in between the first VFET and the second VFET, where the first gate includes a first sidewall of the shared trench, and where the second gate includes a second sidewall of the shared trench. The first sidewall is opposite the second sidewall in the shared trench.

According to one or more embodiments, a non-limiting example method includes holding an analyte in a shared trench between an n-type vertical field-effect transistor (VFET) and a p-type VFET, and simultaneously measuring a first electrical response of the n-type VFET and a second electrical response of the p-type VFET. The method includes determining a characteristic of the analyte according to the first and second electrical responses.

Other embodiments of the present invention implement features of the above-described methods in structures/devices.

Additional technical features and benefits are realized through the techniques of the present invention. Embodiments and aspects of the invention are described in detail herein and are considered a part of the claimed subject matter. For a better understanding, refer to the detailed description and to the drawings.

### BRIEF DESCRIPTION OF THE DRAWINGS

The specifics of the exclusive rights described herein are particularly pointed out and distinctly claimed in the claims at the conclusion of the specification. The foregoing and other features and advantages of the embodiments of the invention are apparent from the following detailed description taken in conjunction with the accompanying drawings in which:

FIG. 1 depicts a cross-sectional view of a portion of an integrated circuit (IC) after fabrication operations according to embodiments of the invention;

FIG. 2 depicts a cross-sectional view of a portion of an IC after fabrication operations according to one or more embodiments of the invention;

FIG. 3 depicts a cross-sectional view of a portion of an IC after fabrication operations according to one or more embodiments of the invention;

FIG. 4 depicts a cross-sectional view of a portion of an IC after fabrication operations according to one or more embodiments of the invention;

FIG. 5 depicts a cross-sectional view of a portion of an IC after fabrication operations according to one or more embodiments of the invention;

FIG. 6 depicts a cross-sectional view of a portion of an IC after fabrication operations according to one or more embodiments of the invention;

FIG. 7 depicts a cross-sectional view of a portion of an IC after fabrication operations according to one or more embodiments of the invention;

FIG. 8 depicts a cross-sectional view of a portion of an IC after fabrication operations according to one or more embodiments of the invention;

FIG. 9 depicts a cross-sectional view of a portion of an IC after fabrication operations according to one or more embodiments of the invention;

FIG. 10 depicts a cross-sectional view of a portion of an IC after fabrication operations according to one or more embodiments of the invention;

FIG. 11 depicts a cross-sectional view of a portion of an IC after fabrication operations according to one or more embodiments of the invention;

FIG. 12 depicts a cross-sectional view of a portion of an IC after fabrication operations according to one or more embodiments of the invention;

FIG. 13 depicts a cross-sectional view of a portion of an IC after fabrication operations according to one or more embodiments of the invention;

FIG. 14 depicts a cross-sectional view of a portion of an IC after fabrication operations according to one or more embodiments of the invention;

FIG. 15 depicts a cross-sectional view of a portion of an IC after fabrication operations according to one or more embodiments of the invention;

FIG. 16 depicts a cross-sectional view of a portion of an IC after fabrication operations according to one or more embodiments of the invention;

FIG. 17 depicts a cross-sectional view of a portion of an IC after fabrication operations according to one or more embodiments of the invention;

FIG. 18 depicts a cross-sectional view of a portion of an IC after fabrication operations according to one or more embodiments of the invention;

FIG. 19 depicts a cross-sectional view of a portion of an IC after fabrication operations according to one or more embodiments of the invention;

FIG. 20 depicts a cross-sectional view of a portion of an IC after fabrication operations according to one or more embodiments of the invention;

FIG. 21 depicts a cross-sectional view of a portion of an IC after fabrication operations according to one or more embodiments of the invention;

FIG. 22 depicts a cross-sectional view of a portion of an IC after fabrication operations according to one or more embodiments of the invention;

FIG. 23 depicts a cross-sectional view of a portion of an IC after fabrication operations according to one or more embodiments of the invention;

FIG. 24 depicts a cross-sectional view of a portion of an IC after fabrication operations according to one or more embodiments of the invention;

FIG. 25 depicts a cross-sectional view of a portion of an IC after fabrication operations according to one or more embodiments of the invention;

FIG. 26 depicts a cross-sectional view of a portion of an IC after fabrication operations according to one or more embodiments of the invention;

FIG. 27 depicts a cross-sectional view of a portion of an IC after fabrication operations according to one or more embodiments of the invention;

FIG. 28 depicts a cross-sectional view of a portion of an IC after fabrication operations according to one or more embodiments of the invention;

FIG. 29 depicts a cross-sectional view of a portion of an IC after fabrication operations according to one or more embodiments of the invention;

FIG. 30 depicts a graph of an example operation of the IC according to one or more embodiments of the invention;

FIG. 31 depicts a graph of an example operation of the IC according to one or more embodiments of the invention; and

FIG. 32 depicts a graph of an example operation of the IC according to one or more embodiments of the invention.

### DETAILED DESCRIPTION

For the sake of brevity, conventional techniques related to semiconductor device and integrated circuit (IC) fabrication may or may not be described in detail herein. Moreover, the various tasks and process steps described herein can be incorporated into a more comprehensive procedure or process having additional steps or functionality not described in detail herein. In particular, various steps in the manufacture of semiconductor devices and semiconductor-based ICs are well known and so, in the interest of brevity, many conventional steps will only be mentioned briefly herein or will be omitted entirely without providing the well-known process details.

Ion-sensitive field-effect transistors (ISFETs) have emerged as a promising platform for manufacturing biosensors because of their miniaturized form-factor, low power consumption, high sensitivity, and feasibility for monolithic integration with other device and circuit components on the chip. As the complementary metal-oxide-semiconductor (CMOS) technology evolves with scaling and new device structures and as integration schemes emerge, there should be adaptation of the ISFET device structures and fabrication methods to take advantage of the benefits made available by the emerging CMOS technologies.

According to one or more embodiments, the present disclosure provides device structures and integration methods for a biosensor device formed of a complementary pair of dual-gate vertical field-effect transistors (VFETs) and a sensing trench, where a sensing gate of the n-channel VFET is coupled to a first sidewall of the sensing trench and a sensing gate of the p-channel VFET is coupled to a second sidewall of the sensing trench. The biosensor device utilizes the benefits of the scaled VFET technologies to achieve a small footprint and enable dense integration. Moreover, the disclosed biosensor device according to one or more embodiments enables a higher signal-to-noise ratio compared to typical biosensors.

In one or more embodiments, a method of operating the biosensor device may include trapping a target analyte in the sensing trench, simultaneously measuring an electrical response of the n-channel VFET and an electrical response of the p-channel VFET, and processing the correlated electrical responses to determine the presence and/or concentration of a target analyte.

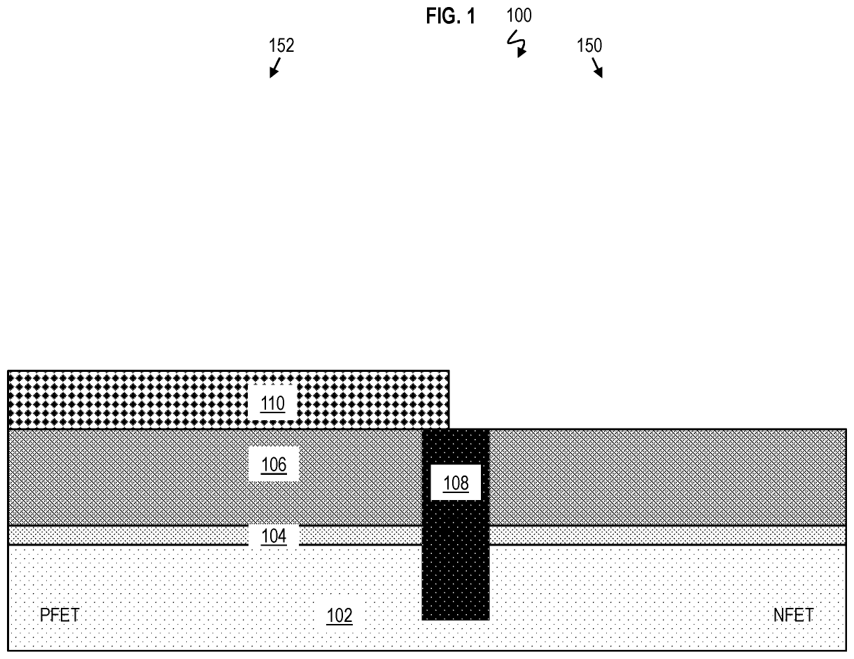

FIGS. 1-29 depict various fabrication operations of forming a portion of an IC 100. Standard semiconductor fabrication techniques can be utilized to fabricate IC 100 as understood by one of ordinary skill in the art. Any suitable deposition techniques and etching techniques can be utilized herein. Turning now to a more detailed description of aspects of the present invention, FIG. 1 depicts a cross-sectional view of a portion of the IC 100 having an NFET 150 and a PFET 152 according to one or more embodiments of the invention. The terms vertical transport field-effect transistor and vertical field-effect transistor can be utilized interchangeably. FIG. 1 depicts the IC 100 after several fabrication operations. FIG. 1 shows a substrate 102 or wafer. In one or more embodiments, the substrate 102 can be undoped silicon, bulk silicon, etc. Other materials can be utilized for substrate 102.

Starting from the substrate 102, a doped layer 104 is epitaxially grown from the substrate 102. A heavily doped layer 106 is epitaxially grown from the doped layer 104. The doped layer 104 is a counter-doped layer to the heavily doped layer 106 above. In one or more embodiments, the doped layer 104 is n-doped with n-type dopants. In one or more embodiments, the heavily doped layer 106 has been doped with p-type dopants and serves as a p-type bottom source/drain epitaxial layer for the PFET 152. Example n-type dopants can include one or more of the following: antimony, arsenic, and phosphorous. Example p-type dopants can include one or more of the following: boron, aluminum, gallium, and indium.

A shallow trench isolation (STI) layer is formed down into the substrate 102. A block mask 110 is formed over the PFET 152 to protect the PFET side during subsequent fabrication processes, while the NFET 150 remains free of block mask 110. As understood by one of ordinary skill in the art, the block mask 110 (and other block masks discussed herein) may include a hardmask layer (e.g., nitride based), an optical planarizing layer (OPL), a silicon anti-reflective coating (SiARC) layer, a photoresist layer, etc., and/or any combination thereof.

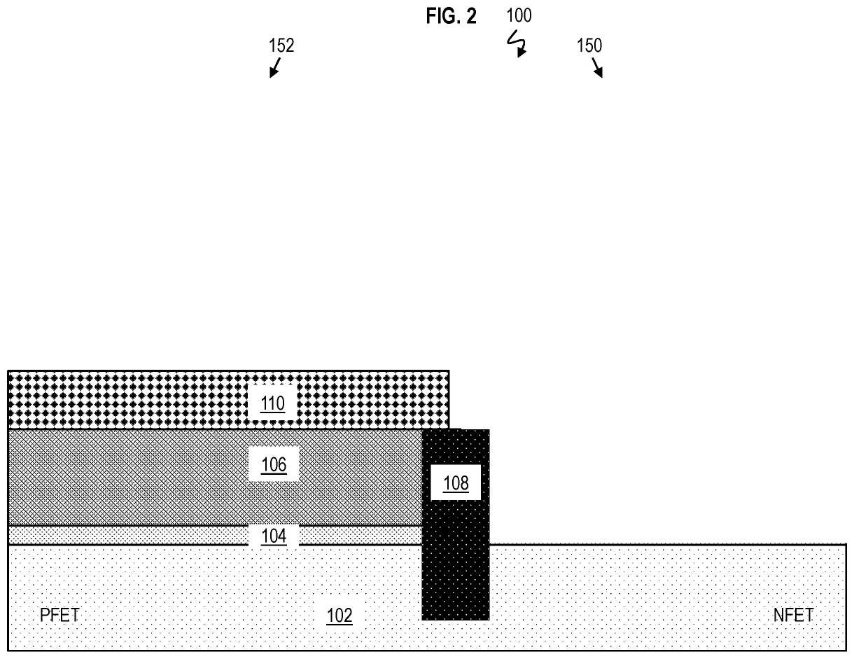

FIG. 2 depicts a cross-sectional view of IC 100 after fabrication operations according to one or more embodiments. Etching is performed to remove the unprotected portions of the heavily doped layer 106 and doped layer 104.

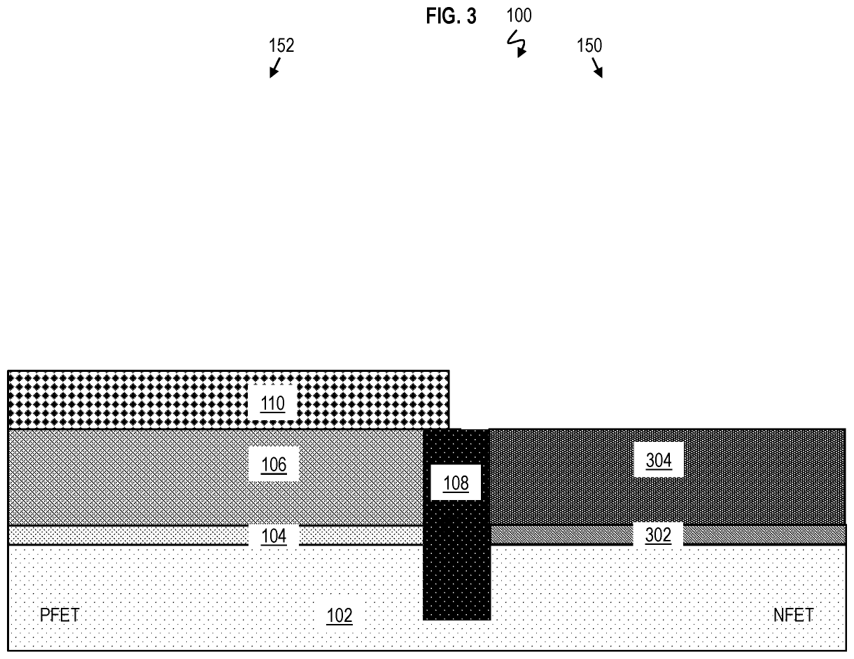

FIG. 3 depicts a cross-sectional view of IC 100 after epitaxially growing a counter-doped layer and a heavily doped NFET bottom source/drain epitaxial layer. A doped layer 302 is epitaxially grown from the substrate 102. A heavily doped layer 304 is epitaxially grown from the doped layer 302. The doped layer 302 is a counter-doped layer to the heavily doped layer 304. In one or more embodiments, the doped layer 302 is p-doped with p-type dopants. In one or more embodiments, the heavily doped layer 304 has been doped with n-type dopants and serves as an n-type bottom source/drain epitaxial layer for the NFET 150. Example n-type dopants can include one or more of the following: antimony, arsenic, and phosphorous. Example p-type dopants can include one or more of the following: boron, aluminum, gallium, and indium.

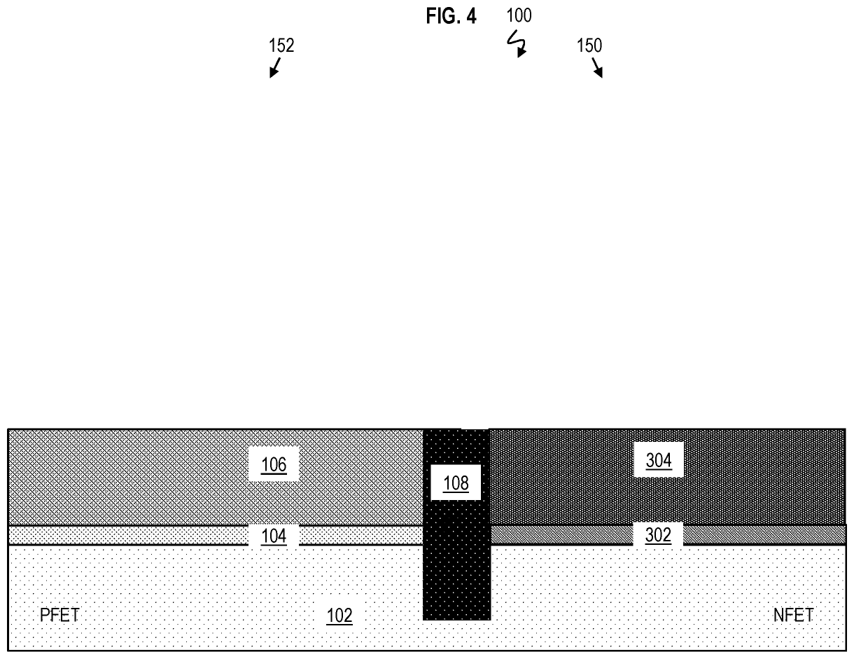

FIG. 4 depicts a cross-sectional view of IC 100 after removal of the block mask according to one or more embodiments. The block mask 110 is removed, and optionally, chemical mechanical polishing/planarization (CMP) is performed to remove epitaxial overgrowth of the heavily doped layer 304.

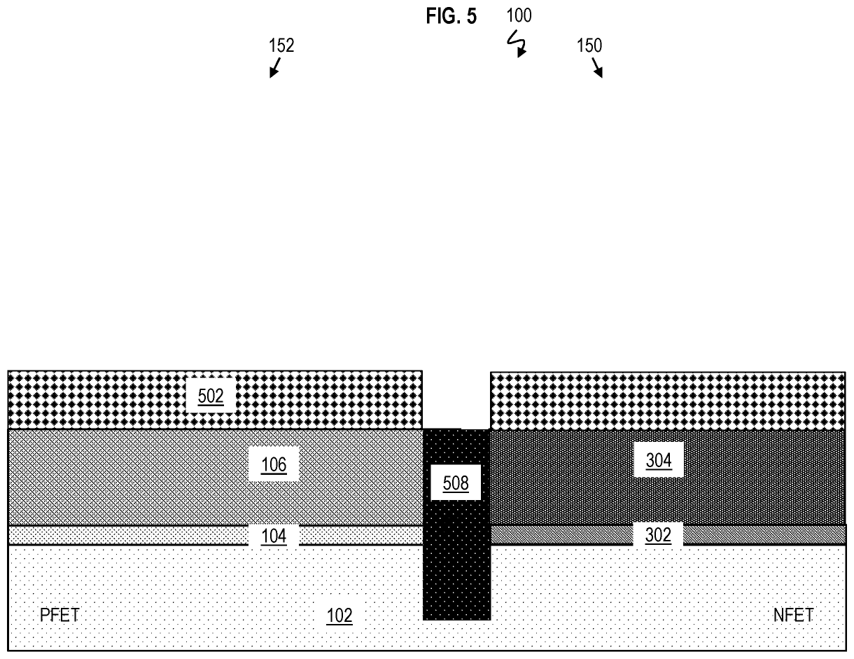

FIG. 5 depicts a cross-sectional view of IC 100 after optional redeposition of an STI layer according to one or more embodiments. A block mask 502 is formed with a trench exposing the STI layer 108 (in FIG. 4). Etching is performed to remove the STI layer 108, which could be a dry etch. The etching may include etching some of the NFET epitaxial material (e.g., the heavily doped layer 304), in order to remove possible epitaxial corner defects. Material for STI layer 508 is deposited.

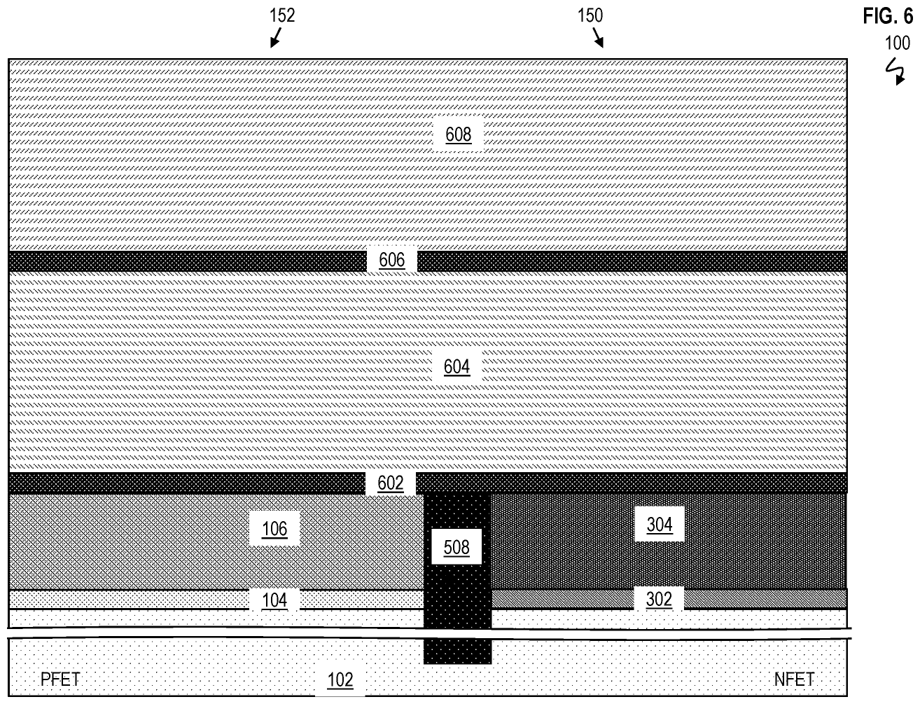

FIG. 6 depicts a cross-sectional view of IC 100 after dummy gate formation according to one or more embodiments. After removal of the block mask 502 and optional planarization, a bottom spacer layer 602 is deposited, dummy gate material 604 is deposited on the bottom spacer layer 602, a top spacer layer 606 is deposited on the dummy gate material 604, and a sacrificial layer 608 is deposited on the top spacer layer 606. Example materials for the dummy gate may include amorphous silicon, polysilicon, etc. Example materials for the bottom spacer layer 602 and the top spacer layer 606 can include SiN, SiBCN, SION, SiCO, etc. The sacrificial layer 608 may include an oxide such as silicon dioxide, aluminum oxide, etc.

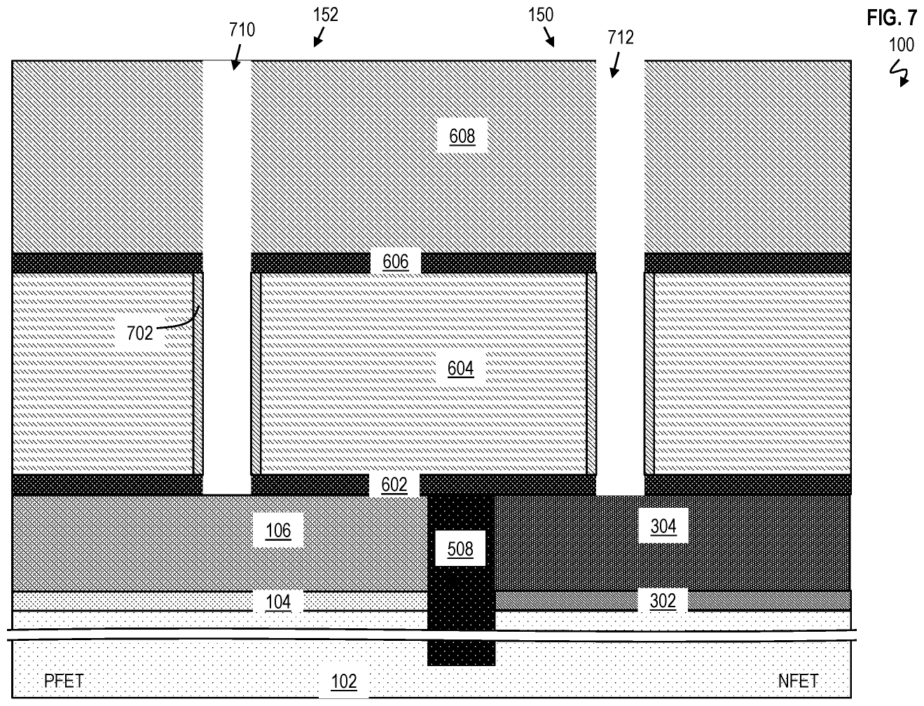

FIG. 7 depicts a cross-sectional view of IC 100 after preparation for channel formation according to one or more embodiments. Etching is performed to form trenches 710 and 712 for FET channel regions. Sacrificial material 702 is formed in the trenches 710 and 712 on the dummy gate material 604 using, for example, plasma oxidation. The sacrificial material 702 can be formed by silicon oxide formation by oxidizing the exposed dummy gate material 604 in the trenches 710 and 712. Using lithography, etching can be performed to remove any sacrificial material grown from the heavily doped layer 106 in trench 710 and the heavily doped layer 304 in trench 712.

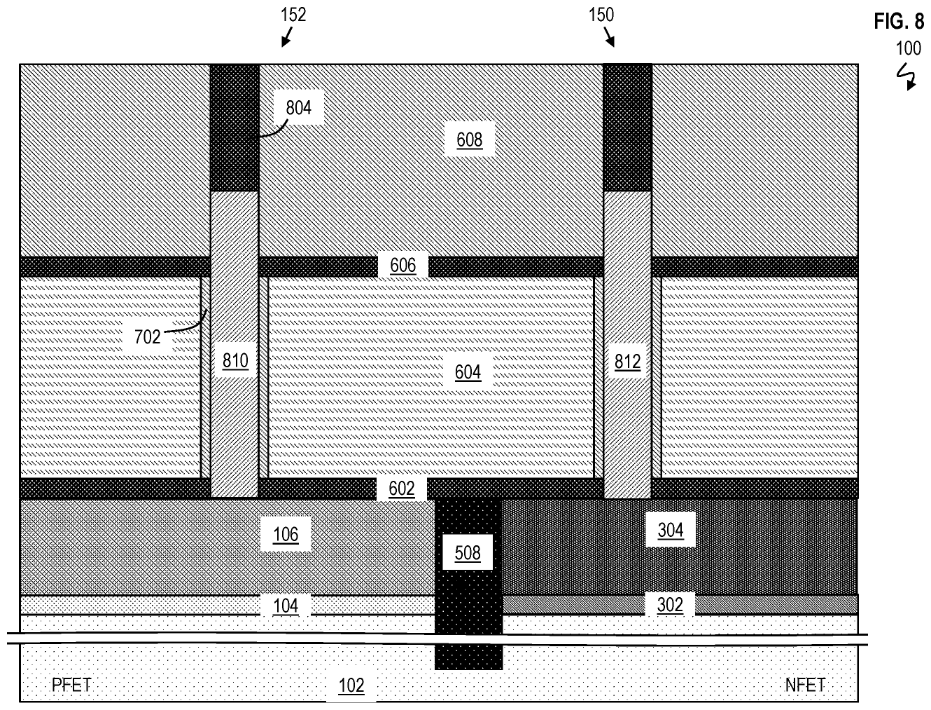

FIG. 8 depicts a cross-sectional view of IC 100 after channel formation for the PFET and NFET according to one or more embodiments. In the trench 710, the vertical channel 810 is epitaxially grown from the heavily doped layer 106. In the trench 712, the vertical channel 812 is epitaxially grown from the heavily doped layer 304. The vertical channels 810 and 812 may be silicon material with any desired dopants. Any overgrowth of the materials of the vertical channels 810 and 812 can be planarized using, for example, CMP. The vertical channels 810 and 812 are selectively recessed, and the remaining space is filled with a cap layer 804. The cap layer 804 may be a nitride cap.

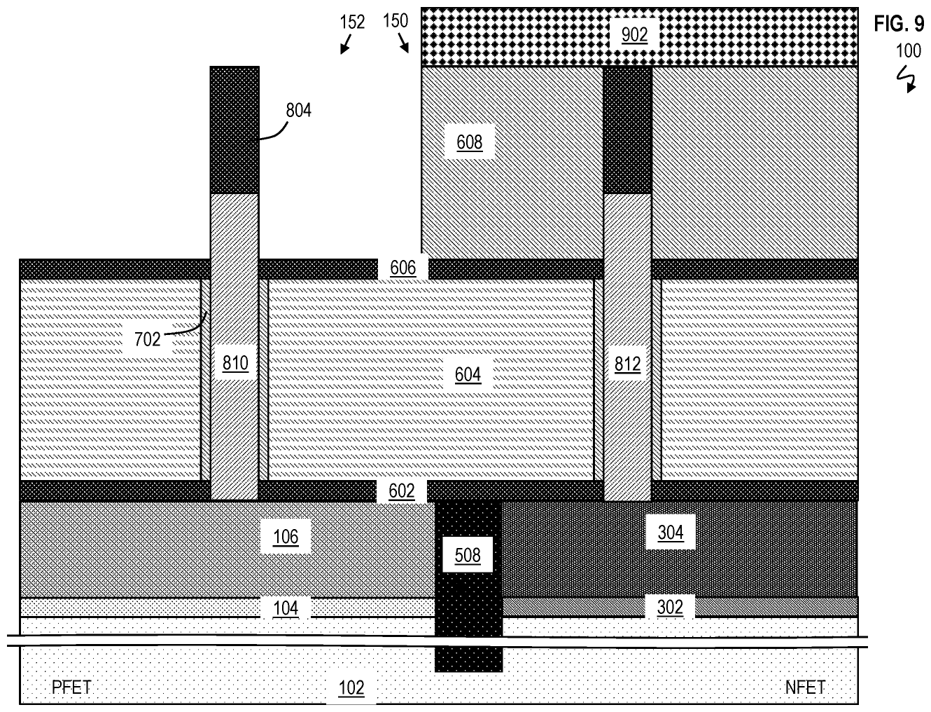

FIG. 9 depicts a cross-sectional view of IC 100 after channel exposure for the PFET according to one or more embodiments. A block mask 902 is formed to protect the NFET side. Etching is performed to selectively remove portions of the sacrificial layer 608 unprotected by the block mask 902. After etching, the upper part of the vertical channel 810 is exposed for source/drain formation.

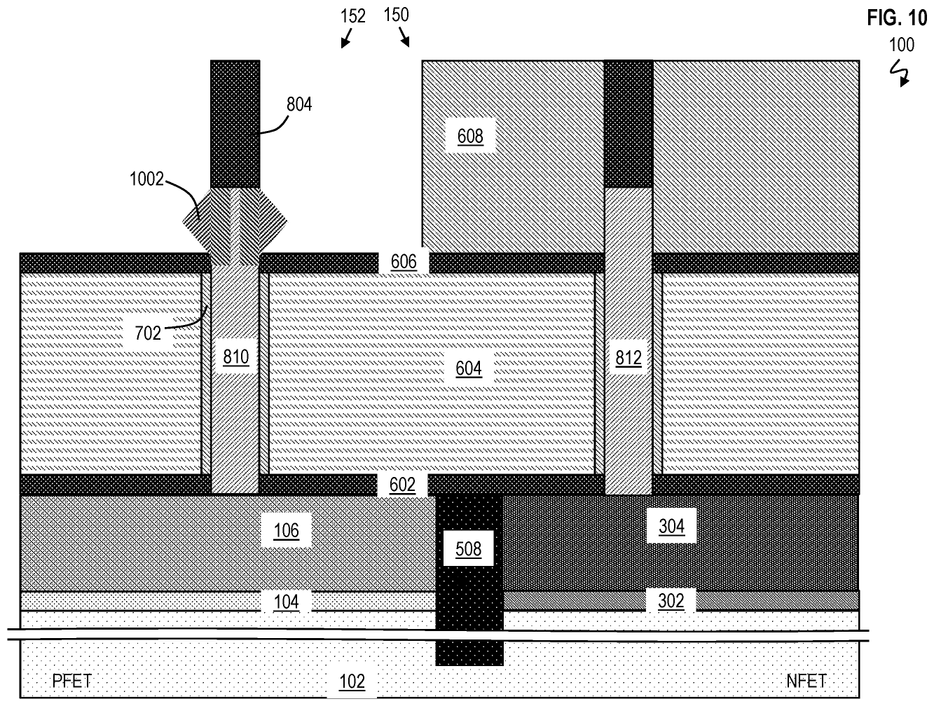

FIG. 10 depicts a cross-sectional view of IC 100 after top source/drain formation for the PFET according to one or more embodiments. Etching is performed to laterally recess an exposed upper portion of the vertical channel 810. As can be seen, the upper portion of the vertical channel 810 is thinned. A top source/drain layer 1002 is epitaxially grown on the thinned upper portion of the vertical channel 810. The top source/drain layer 1002 of the PFET 152 is a highly doped layer. The top source/drain layer 1002 is p-doped with p-type dopants. The block mask 902 is removed.

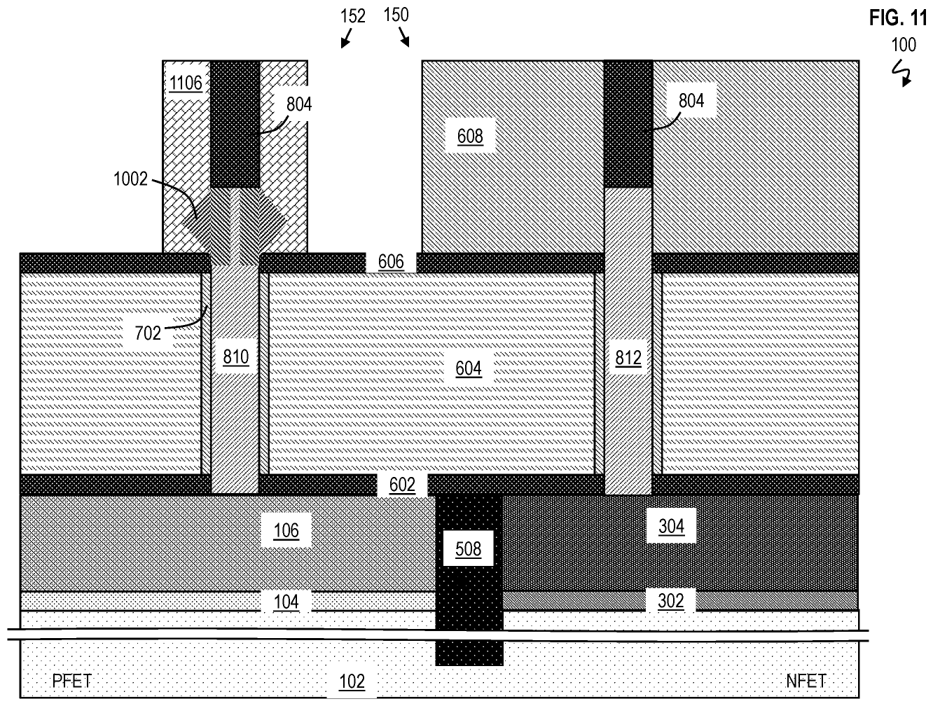

FIG. 11 depicts a cross-sectional view of IC 100 after spacer formation according to one or more embodiments. A spacer layer 1106 is formed around the top source/drain layer 1002. Etching can be performed to pattern the spacer layer 1106.

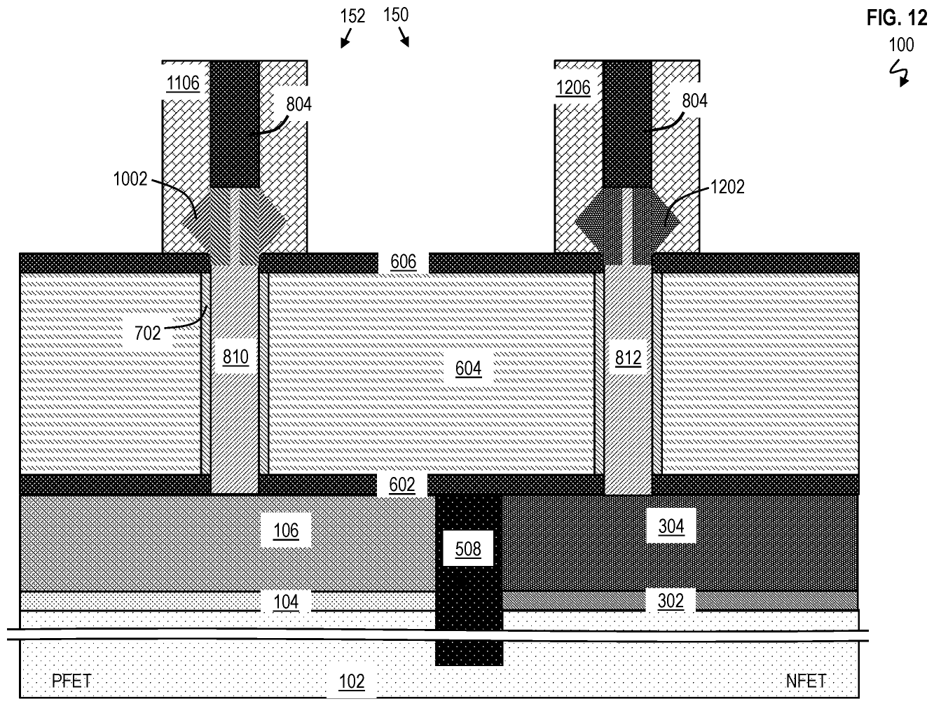

FIG. 12 depicts a cross-sectional view of IC 100 after top source/drain formation and spacer formation according to one or more embodiments. Analogous to FIG. 9, a block mask (not shown) is formed on the PFET side, etching is performed to selectively remove the sacrificial layer 608, and the upper part of the vertical channel 812 is exposed for source/drain formation. Analogous to FIG. 10, etching is performed to laterally recess an exposed upper portion of the vertical channel 812, a top source/drain layer 1202 is epitaxially grown on the thinned upper portion of the vertical channel 812. The top source/drain layer 1202 of the NFET 150 is a highly doped layer. The top source/drain layer 1202 is n-doped with n-type dopants. A spacer layer 1206 is formed around the top source/drain layer 1202. Etching is performed to pattern the spacer layer 1206.

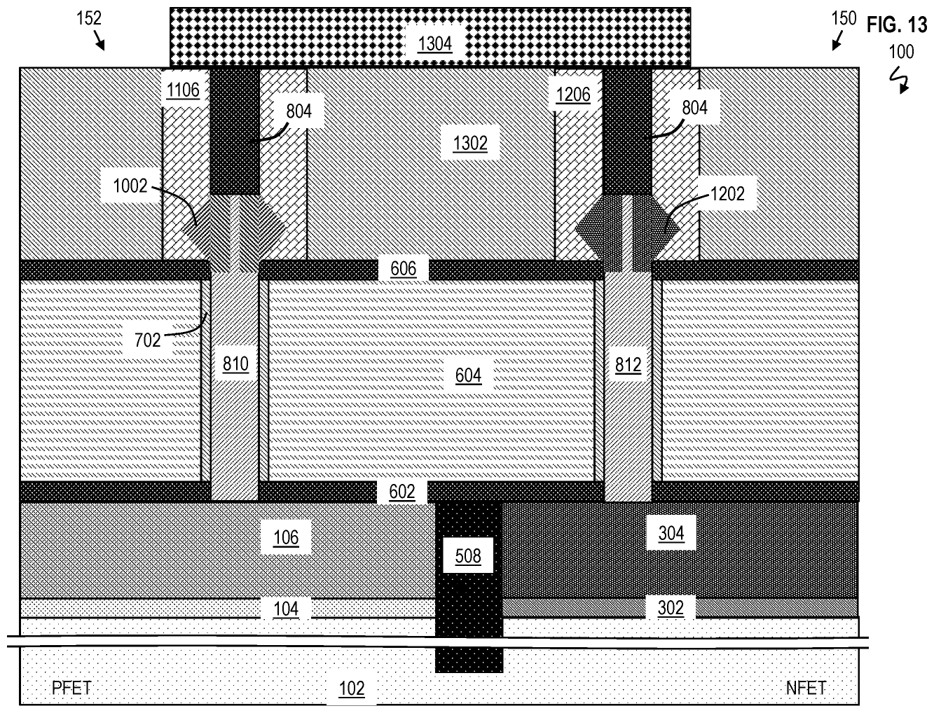

FIG. 13 depicts a cross-sectional view of IC 100 after block mask covering of the future biosensor trench region according to one or more embodiments. A sacrificial layer 1302 is deposited as a fill material, and CMP is performed to etch the sacrificial layer 1302 back to the top of the cap layer 804 (e.g., nitride cap/spacer). The sacrificial layer 1302 may be an oxide material such as silicon oxide, aluminum oxide, etc. A block mask 1304 is deposited and patterned to cover the future biosensor trench region between the PFET 152 and the NFET 150.

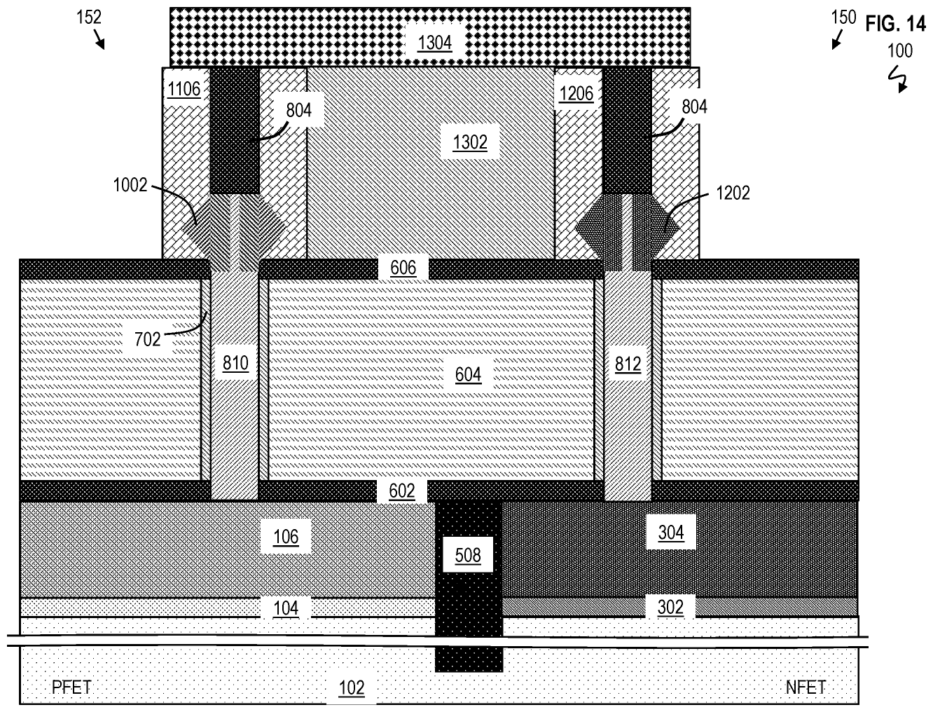

FIG. 14 depicts a cross-sectional view of IC 100 after removal of oxide material according to one or more embodiments. While the future biosensor trench region remains protected by the block mask 1304, the exposed portion of the sacrificial layer 1302 is selectively removed, which exposes the top spacer layer 606.

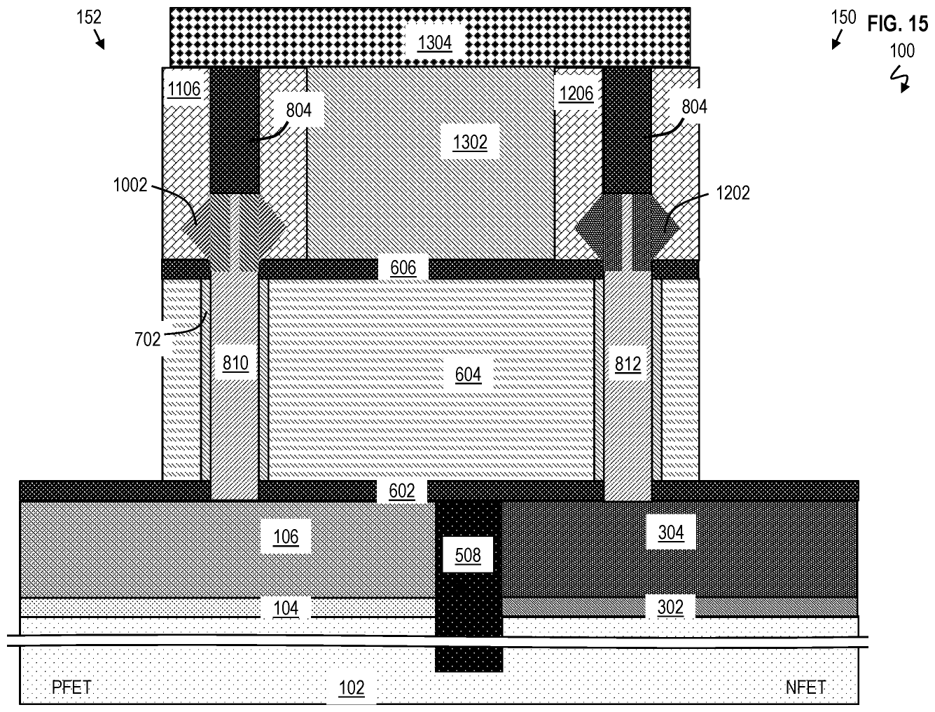

FIG. 15 depicts a cross-sectional view of IC 100 after further recessing according to one or more embodiments. While the future biosensor trench region remains protected by the block mask 1304, the exposed portion of the top spacer layer 606 is removed, and the subsequently exposed portion of the dummy gate material 604 is removed, such that the bottom spacer layer 602 is exposed. Although the block mask 1304 may include nitride material, the material of the top spacer layer 606 can be different for better selectivity during etching. Also, the top spacer layer 606 is much thinner than the block mask 1304. Further, minor etching of the block mask 1304 may occur without diminishing its protection.

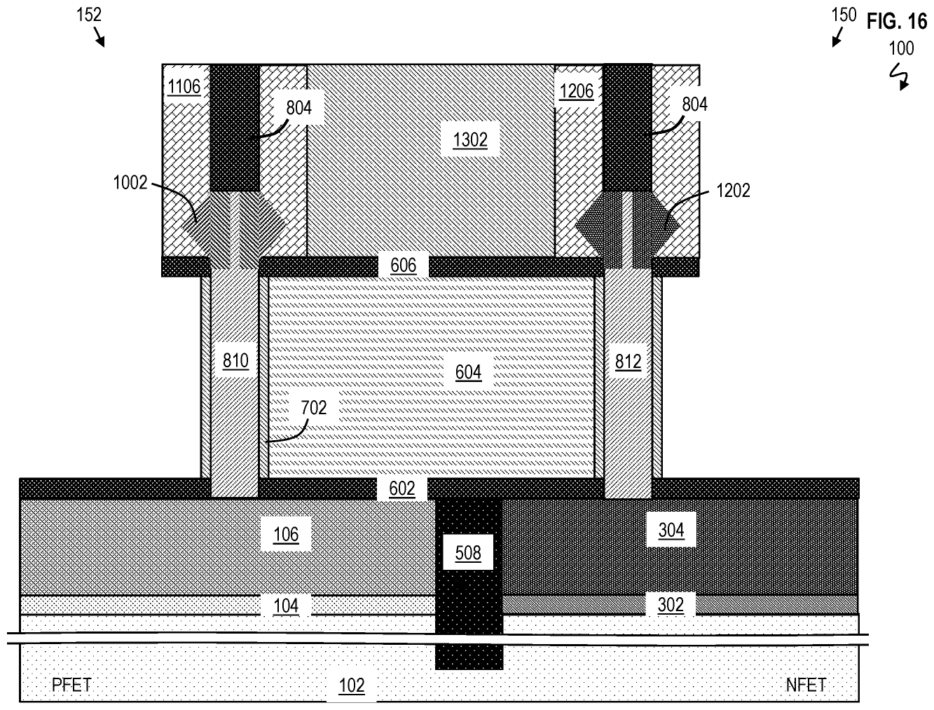

FIG. 16 depicts a cross-sectional view of IC 100 after further removing the dummy gate according to one or more embodiments. Selective etching is performed to remove the exposed portion of the dummy gate material 604, which may be amorphous silicon. This exposes the sacrificial material 702 on one side of the vertical channels 810 and 812. The block mask 1304 can be removed.

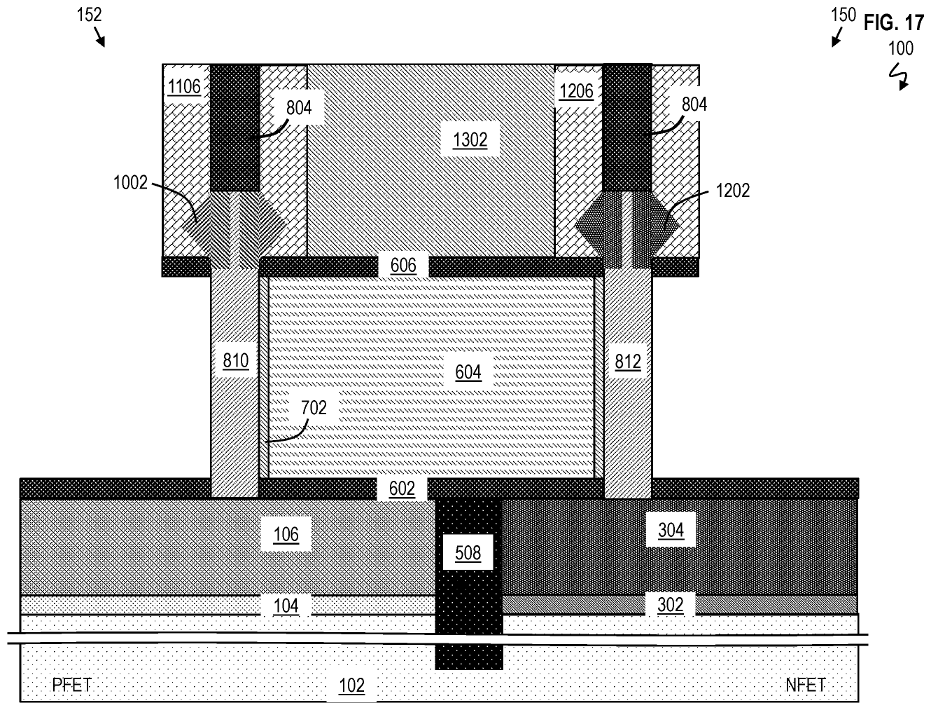

FIG. 17 depicts a cross-sectional view of IC 100 after etching according to one or more embodiments. Etching is performed to selectively remove the exposed portion of the sacrificial material 702 on one side of each of the vertical channels 810 and 812.

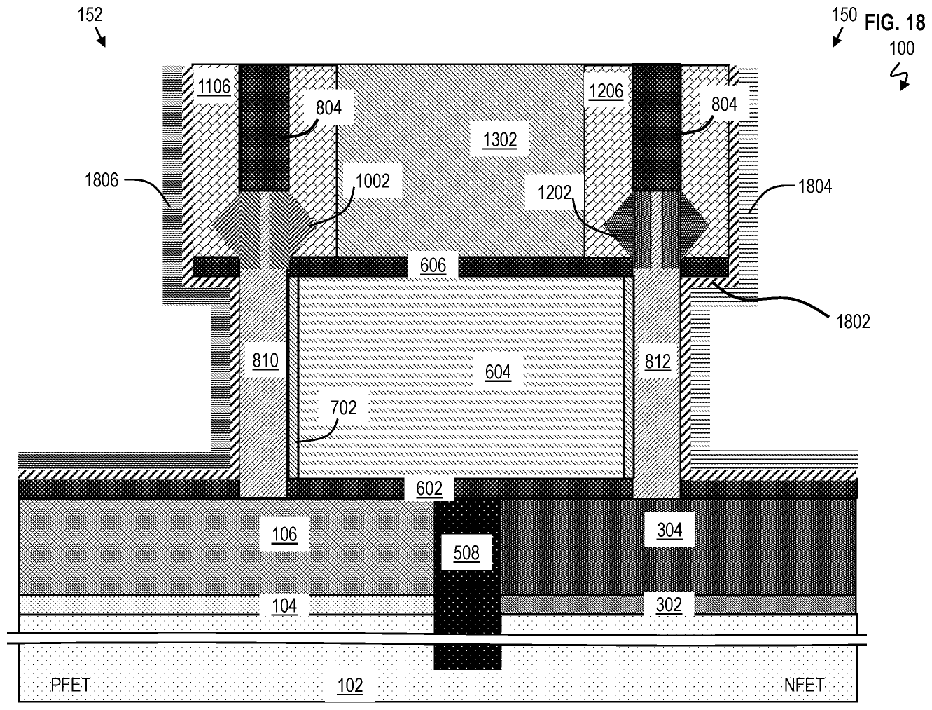

FIG. 18 depicts a cross-sectional view of IC 100 after a replacement metal gate process according to one or more embodiments. A gate dielectric material 1802 is formed on the exposed side of the vertical channels 810 and 812. The gate dielectric material 1802 is a high-k dielectric material. Work function material 1806 is formed on the PFET side, and work function material 1804 is formed on the NFET side, using standard techniques as understood by one of ordinary skill in the art. The work function material 1806 can include PFET work function materials/metals. The work function material 1804 can include NFET work function materials/metals.

A high-k gate dielectric layer can be, for example, a dielectric material with a dielectric constant that is greater than the dielectric constant of silicon dioxide (i.e., greater than 3.9). Exemplary high-k dielectric materials include, but are not limited to, hafnium (Hf)-based dielectrics (e.g., hafnium oxide, hafnium silicon oxide, hafnium silicon oxynitride, hafnium aluminum oxide, etc.) or other suitable high-k dielectrics (e.g., aluminum oxide, tantalum oxide, zirconium oxide, etc.).

Work function materials can include a work function metal that is immediately adjacent to the gate dielectric layer and that is preselected in order to achieve an optimal gate conductor work function given the conductivity type of the VFET. For example, the optimal gate conductor work function for the PFETs can be, for example, between about 4.9 eV and about 5.2 eV. With respect to work function materials for PFETs, exemplary metals (and metal alloys) having a work function within or close to this range include, but are not limited to, ruthenium, palladium, platinum, cobalt, and nickel, as well as metal oxides (aluminum carbon oxide, aluminum titanium carbon oxide, etc.) and metal nitrides (e.g., titanium nitride, titanium silicon nitride, tantalum silicon nitride, titanium aluminum nitride, tantalum aluminum nitride, etc.). The optimal gate conductor work function for NFETs can be, for example, between 3.9 eV and about 4.2 eV. With respect to work function materials for NFETs, exemplary metals (and metal alloys) having a work function within or close to this range include, but are not limited to, hafnium, zirconium, titanium, tantalum, aluminum, and alloys thereof, such as, hafnium carbide, zirconium carbide, titanium carbide, tantalum carbide, and aluminum carbide. The metal layer(s) can further include a fill metal or fill metal alloy, such as tungsten, a tungsten alloy (e.g., tungsten silicide or titanium tungsten), cobalt, aluminum or any other suitable fill metal or fill metal.

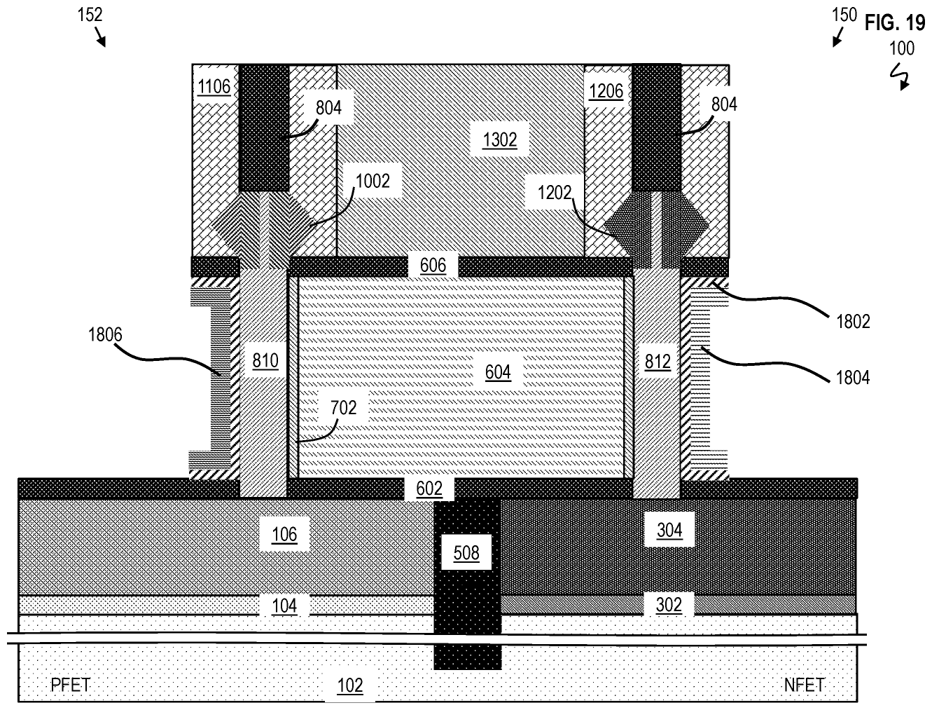

FIG. 19 depicts a cross-sectional view of IC 100 after an anisotropic high-k/metal gate etch according to one or more embodiments. Exposed portions of the gate dielectric material 1802 and work function materials 1804 and 1806 are etched, while portions protected by the spacer layers 1106 and 1206 remain.

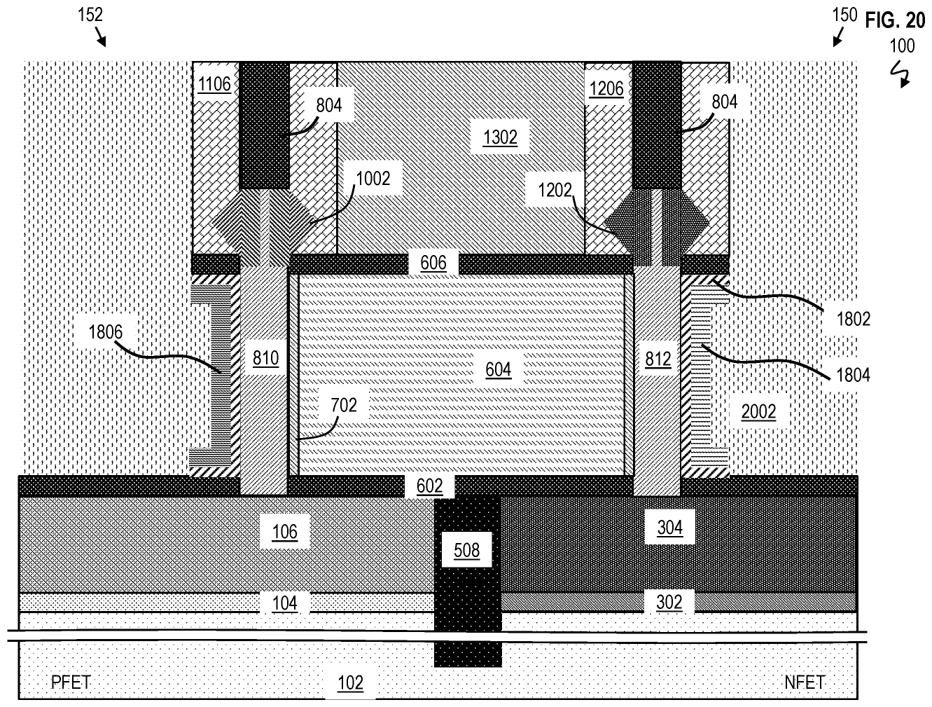

FIG. 20 depicts a cross-sectional view of IC 100 after metal gate fill according to one or more embodiments. A metal gate material 2002 is deposited over the gate dielectric material 1802 and work function materials 1804 and 1806. The metal gate material 2002 is a gate conductor and can be deposited using any suitable deposition process. Planarization is performed on the metal gate material 2002, for example, using CMP, to polish the metal gate material 2002. Examples of suitable conductive metals include aluminum (Al), platinum (Pt), gold (Au), tungsten (W), titanium (Ti), or any combination thereof.

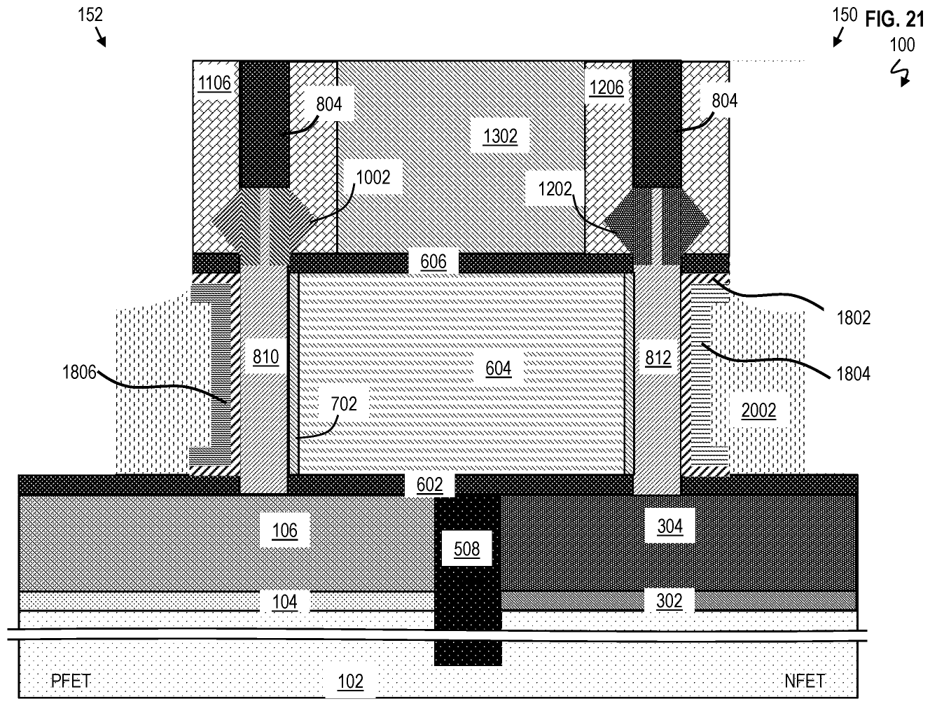

FIG. 21 depicts a cross-sectional view of IC 100 after metal gate recess according to one or more embodiments. The metal gate material 2002 is partially recessed using, for example, reactive ion etching (RIE). Lithography is performed to further pattern and etch the metal gate material 2002.

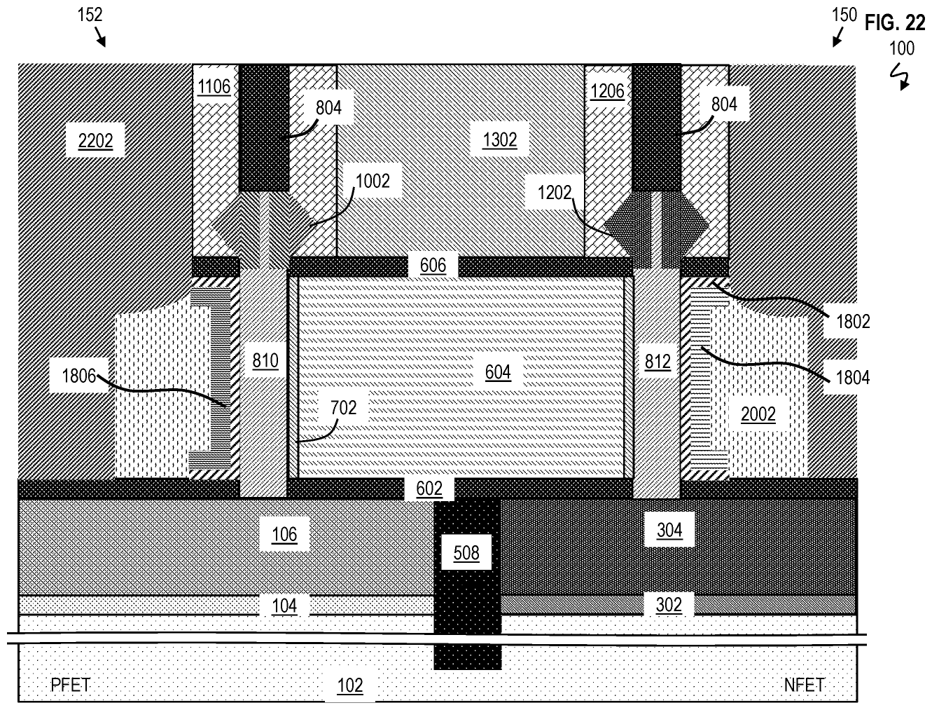

FIG. 22 depicts a cross-sectional view of IC 100 after interlayer dielectric formation according to one or more embodiments. An interlayer dielectric (ILD) layer 2202 is deposited, and planarization is performed. The ILD layer 2202 can include low-k dielectric materials and ultra-low-k dielectric materials.

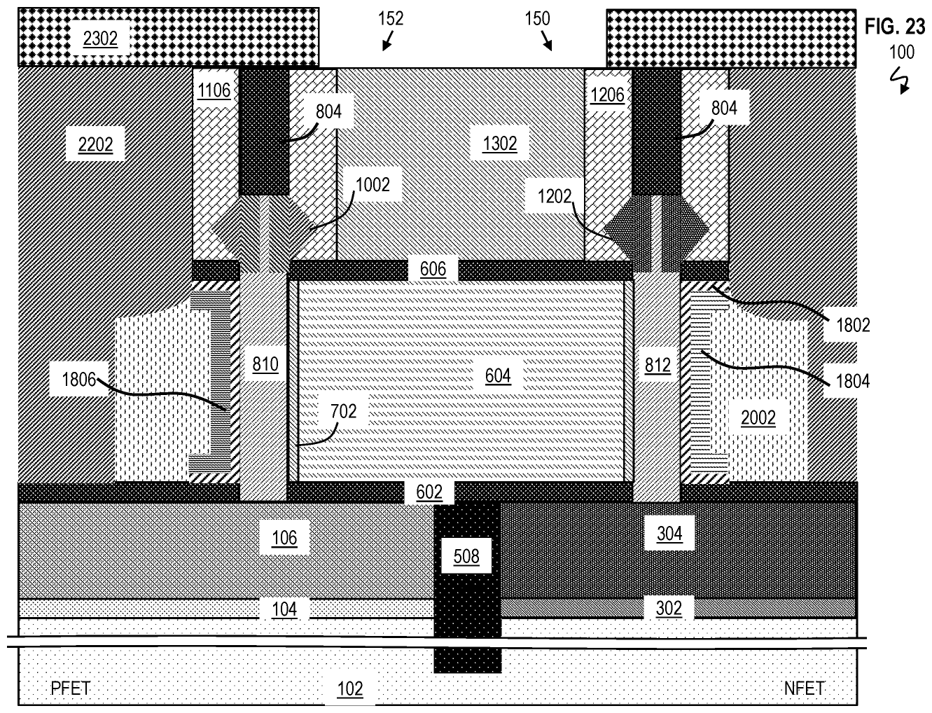

FIG. 23 depicts a cross-sectional view of IC 100 after preparation to open future biosensor trench region according to one or more embodiments. A block mask 2302 is deposited and patterned to expose the biosensor trench region, in preparation for subsequent etching.

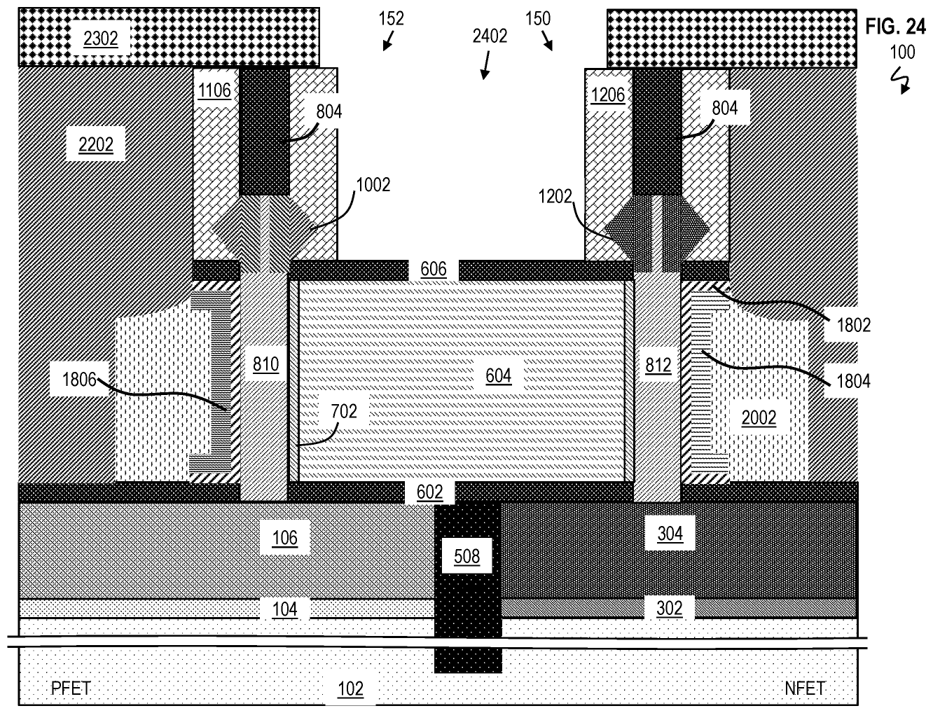

FIG. 24 depicts a cross-sectional view of IC 100 after opening the biosensor trench according to one or more embodiments. Etching is performed to open a shared trench 2402. The sacrificial layer 1302 may be etched with a wet etch or dry etch chemistry. The sacrificial layer 1302 can be an oxide material, and any suitable etching can be performed to remove the oxide material.

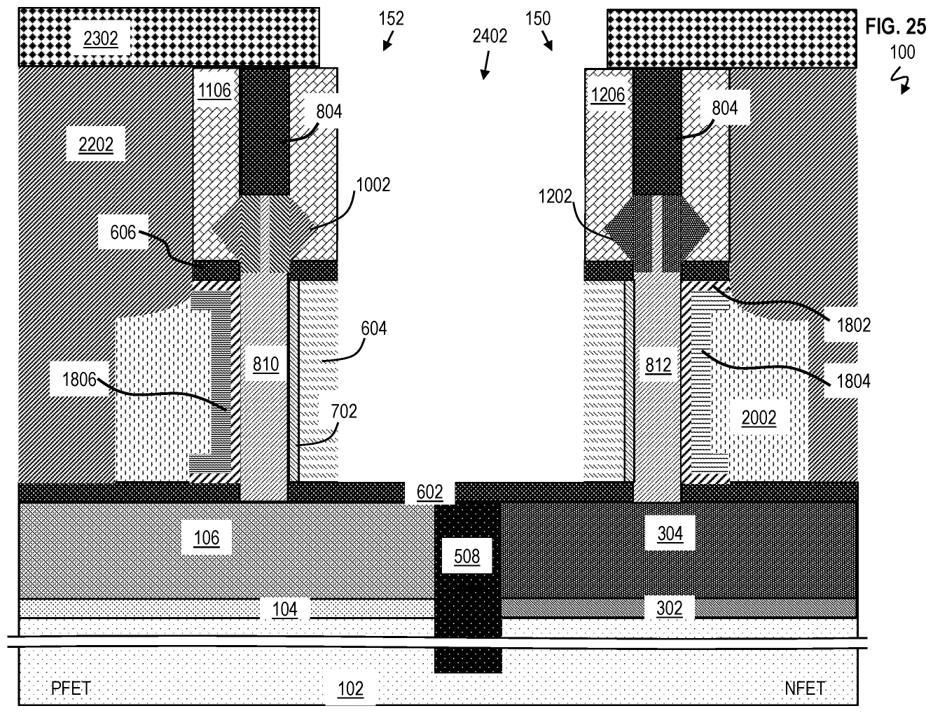

FIG. 25 depicts a cross-sectional view of IC 100 after further opening the biosensor trench according to one or more embodiments. Etching is performed to remove the top spacer layer 606 and a portion of the dummy gate material 604, which further opens the shared trench 2402 such that the bottom spacer layer 602 is exposed. The top spacer layer 606 is a nitride material, and a RIE etch can be utilized to remove the top spacer layer 606 or another type of dry etch. The RIE etch can continue and be used to remove the portion of the dummy gate material 604 (e.g., amorphous silicon). Also, the dummy gate material can be removed by a dry etch or a wet etch. In one or more embodiments, a RIE etch could have been utilized to remove the sacrificial layer 1302 (in FIG. 24), along with the top spacer layer 606 and the dummy gate material 604 in FIG. 25.

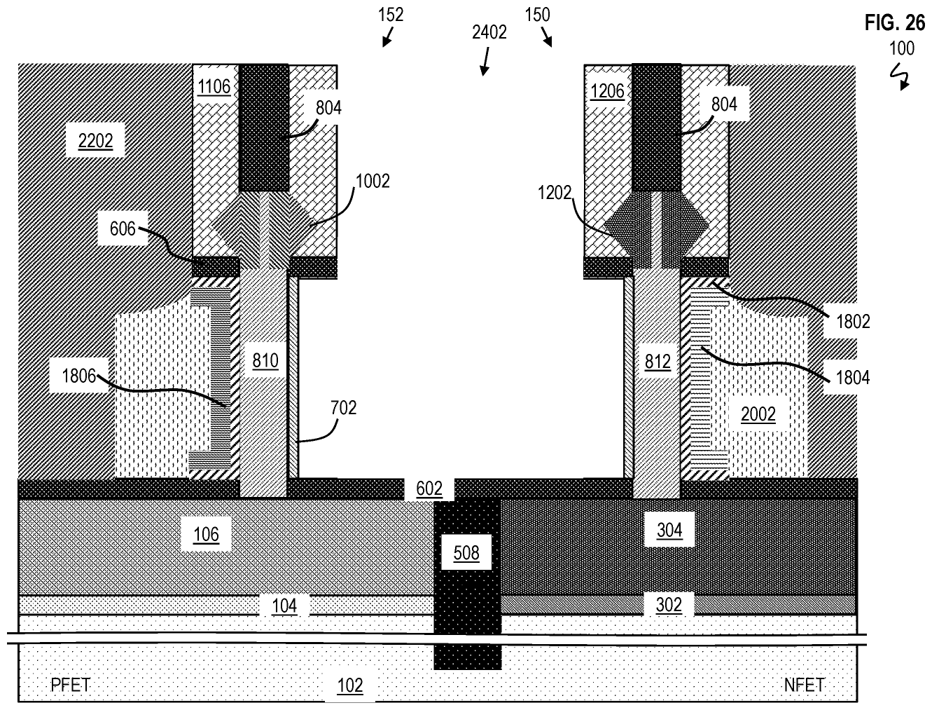

FIG. 26 depicts a cross-sectional view of IC 100 after cleaning the biosensor trench according to one or more embodiments. Etching is performed to remove the remainder of the dummy gate material 604 along the vertical channels 810 and 812 in the shared trench 2402. A wet etch chemistry may be utilized. The block mask 2302 is removed.

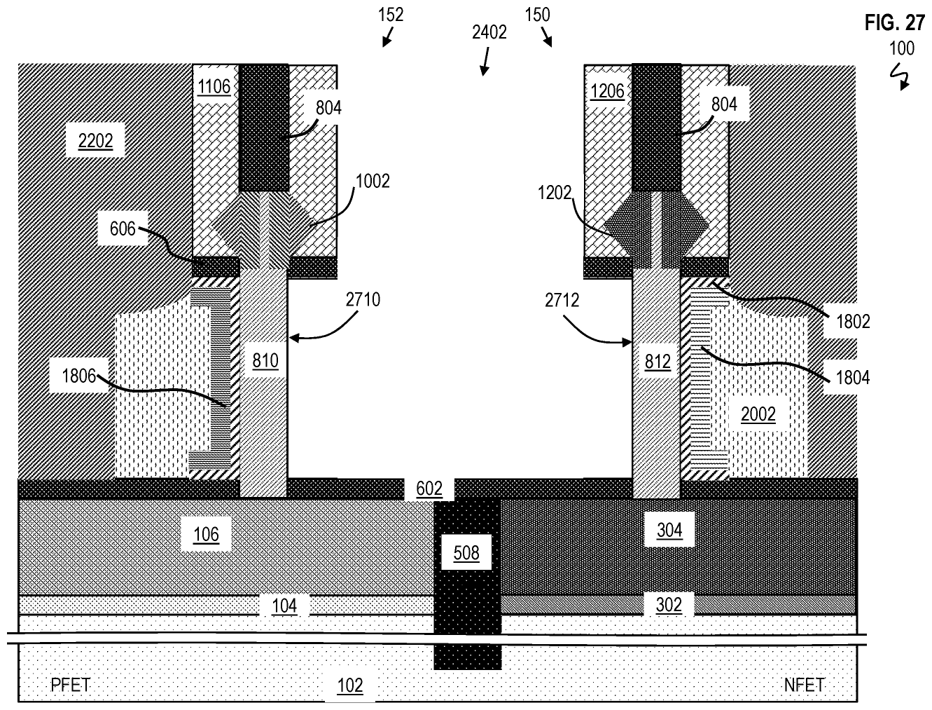

FIG. 27 depicts a cross-sectional view of IC 100 after further cleaning the biosensor trench according to one or more embodiments. Etching is performed to remove the sacrificial material 702 along the surface of the vertical channels 810 and 812 in the shared trench 2402. Accordingly, a side surface of each of the vertical channels 810 and 812 is exposed in the shared trench 2402. For example, sidewall 2710 of vertical channel 810 and sidewall 2712 of vertical channel 812 both form the shared trench 2402.

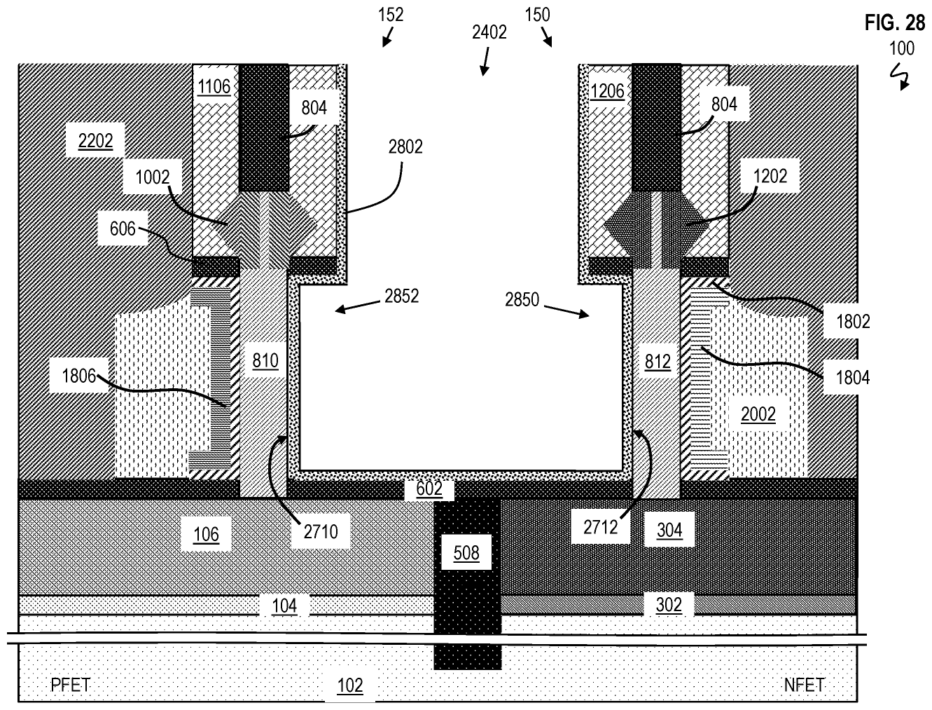

FIG. 28 depicts a cross-sectional view of IC 100 after a biosensing surface coating and/or functionalization layer is deposited in the biosensor trench according to one or more embodiments. A biosensing layer 2802 can be deposited in the shared trench 2402. Examples materials of the biosensing layer 2802 can include HfO₂, Al₂O₃, La₂O₃, and/or SiO₂. Other examples of biosensing coatings may include platinum, Pt-silicides, other noble metals and their silicides, gold, graphene, titanium nitride (TiN), niobium nitride (NbN), vanadium nitride (VN), other conductive transition metal nitrides, and any combinations thereof.

The PFET 152 has a gate 2852 and the NFET 150 has a gate 2850. On one side of the vertical channel 810, the gate 2852 of the PFET 152 includes the gate dielectric material 1802 and the work function material 1806. On the opposite side of the vertical channel 810, the gate 2852 of the PFET 152 includes the shared trench 2402 as well as the biosensing layer 2802. Accordingly, the gate 2852 can be formed of the gate dielectric material 1802, the work function material 1806, and the shared trench 2402 (which includes the biosensing layer 2802).

Similarly, on one side of the vertical channel 812, the gate 2850 of the NFET 150 includes the gate dielectric material 1802 and the work function material 1804. On the opposite side of the vertical channel 812, the gate 2850 of the NFET 150 includes the shared trench 2402 as well as the biosensing layer 2802. Accordingly, the gate 2850 can be formed of the gate dielectric material 1802, the work function material 1804, and the shared trench 2402 (which includes the biosensing layer 2802).

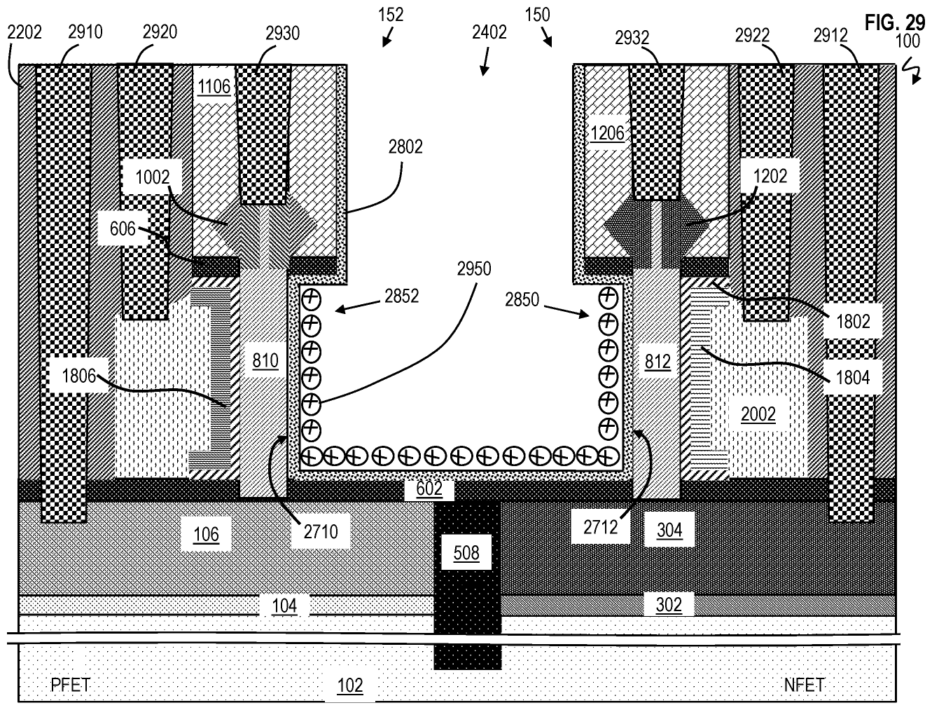

FIG. 29 depicts a cross-sectional view of IC 100 after metallization according to one or more embodiments. Using lithography with patterned resist materials, etching may be performed to form trenches, and the trenches are filled with metal to form bottom source/drain contact 2910, top source/drain contact 2930, and gate contact 2920 for the PFET 152, as well as bottom source/drain contact 2912, top source/drain contact 2932, and gate contact 2922 for the NFET 150. Example metals utilized to form the contacts may include aluminum (Al), platinum (Pt), gold (Au), tungsten (W), titanium (Ti), or any combination thereof. It should be appreciated that a silicide may be formed between the contact metal and the semiconductor material of the source/drains.

The shared trench 2402 is a shared gate between the NFET 150 and PFET 152. The shared trench 2402 is adjacent to and formed by the vertical channel 810 of the PFET 152 and the vertical channel 812 of the NFET 150, such that the shared trench 2402 affects the flow of electrical current through both the vertical channel 810 and the vertical channel 812 according to an analyte 2950 in the shared trench 2402. Accordingly, the biosensor trench allows the detection and/or characterization of the analyte 2950 in the shared trench 2402. Although the analyte 2950 is illustrated with a positive charge, the analyte may have a negative charge. In one or more embodiments, the analyte may have a neutral charge or nearly neutral charge.

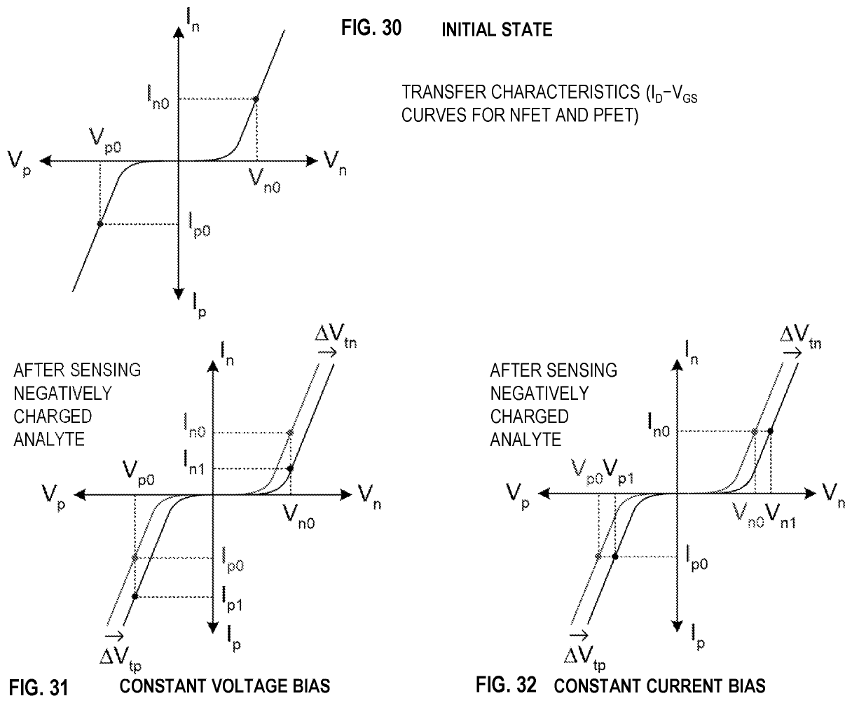

FIG. 30 depicts an example graph of an initial operational state of the IC 100 which is a dual gate biosensor according to one or more embodiments. The graph in FIG. 30 illustrates the initial state of the transfer characteristics for the drain currents and gate-to-source voltages of the NFET 150 and PFET 152. FIG. 31 depicts an example graph of an operational state of the IC 100 with a constant voltage bias after sensing a negatively charged analyte according to one or more embodiments. FIG. 32 depicts an example graph of an operational state of the IC 100 with a constant current bias after sensing a negatively charged analyte according to one or more embodiments. In general, the threshold voltage (Vt) of an FET is the minimum gate-to-source voltage (Vgs) that is needed to turn the FET on and create a conducting path between the source terminal and the drain terminal. Vt is determined by several factors including the doping levels in the MOSFET channel.

The NFET 150 and PFET 152 may (but not necessarily) be biased at a constant voltage or at a constant current, as depicted respectively in FIGS. 31 and 32. The NFET 150 and PFET 152 may (but not necessarily) be biased symmetrically, i.e., Iₙ₀=−Iₚ₀ and Vₙ₀=−Vₚ₀, where Iₙ₀ is the drain current of the NFET, Iₚ₀ is the drain current of the PFET, Vₙ₀ is the gate-to-source voltage of the NFET, and Vₚ₀ is the gate-to-source voltage of the PFET, in the absence of the target analyte. Also, NFET 150 and PFET 152 may (but not necessarily) have, via design and/or back-gate control, the same threshold voltage magnitudes, i.e., Vₜₙ=−Vₜₚ, where Vₜₙ is the threshold voltage for the NFET and Vₜₚ is the threshold voltage for the PFET.

Sensing an analyte 2950 results in a threshold voltage shift (ΔVₜ) for NFET and PFET in opposite directions. For example, for negatively charged analytes, Vₜₙ is increased but |Vₜₚ| is decreased (| | denotes absolute value). As a result, at constant voltage, Iₙ is decreased from Iₙ₀ to Iₙ₁ while |Iₚ| is increased from |Iₚ₀| to |Iₚ₁|, where Iₙ is the drain current through the vertical channel of NFET 150 and Iₚ is the drain current through the vertical channel of PFET 152. For a constant current, Vₙ is increased from Vₙ₀ to Vₙ₁ while |Vₚ| is decreased from |Vₚ₀| to |Vₚ₁|, where Vₙ is the gate-to-source voltage of the NFET and Vₚ is the gate-to-source voltage of the PFET.

As technical effects and benefits, the disclosed vertical transistor dual gate biosensor (e.g., IC 100, i.e., ISFET) enables a higher sensitivity compared to transistor having of a single NFET or a single NFET, since |ΔIₙ|+|ΔIₚ|>|ΔIₙ| and |ΔIₙ|+|ΔIₚ|>|ΔIₚ| at constant voltage bias, and |ΔVₙ|+|ΔVₚ|>|ΔVₙ| and |ΔVₙ|+|ΔVₚ|>|ΔVₚ| at constant current bias, providing a larger sensed signal. In addition, the disclosed vertical transistor dual gate biosensor (e.g., IC 100) enables higher signal-to-noise ratios by allowing differential sensing, whereas a single NFET or a single NFET lacks a reference (coupled pair) for cancelling out correlated noise. In particular, a target analyte such as a single molecule in the shared trench can be sensed simultaneously by the NFET and the PFET in the disclosed vertical transistor dual gate biosensor, and the correlated noise appearing simultaneously in the measured NFET and PFET characteristic can be factored out.

As technical effects and benefits, the disclosed vertical transistor dual gate biosensor (e.g., IC 100, i.e., ISFET) also provides a higher sensitivity and overall higher signal-to-noise ratio compared to transistor having an NFET coupled to a reference NFET (or a PFET coupled to a reference PFET). A reference FET (NFET or PFET) does not contribute to the sensed signal in the state-of-the-art, so the signal advantage provided by the disclosed vertical transistor dual gate biosensor (e.g., IC 100) as described above is still applicable. The noise advantage of the vertical transistor dual gate biosensor (e.g., IC 100) is of the same order as a referenced pair, because correlated noise is independent of current polarity, to the first order.

Moreover, the signal advantage of the disclosed vertical transistor dual gate biosensor (e.g., IC 100, i.e., ISFET) allows operation at higher currents (e.g., in the saturation regime) where the low-frequency (1/f) flicker noise is smaller, thus allowing a higher signal-to-noise ratio for the same sensitivity. The disclosed vertical transistor dual gate biosensor (e.g., IC 100) utilizes the benefits of the scaled VFET technologies to achieve a small footprint and enable dense integration. The disclosed vertical transistor dual gate biosensor (e.g., IC 100) can be co-integrated monolithically with other VFET based devices and circuits on the same chip.

It should be noted that the operation examples described herein are not restrictive. Any operation and/or measurement approach (hardware of software) taking advantage of the device structure and/or basic operation principles described can be utilized. Any known measurement hardware and/or circuitry, such as differential amplifiers, instrumentation amplifiers, sense amplifiers, etc., and hardware- and/or software-based approaches known for sensor readout and analysis may be used in conjunction with the disclosed structures and methods.

According to one or more embodiments, a method of forming a semiconductor structure includes forming a first vertical field-effect transistor (VFET) (e.g., NFET 150 (or PFET 152)) having a first gate (e.g., gate 2850 (or gate 2852)), and forming a second VFET (e.g., PFET 152 (or NFET 150)) having a second gate (e.g., gate 2852 (or gate 2850)). The first and second gates comprising a shared trench (e.g., shared trench 2402) formed in between the first VFET and the second VFET. The first gate (e.g., gate 2850) includes a first sidewall (e.g., the sidewall 2712) of the shared trench 2402, where the second gate (e.g., gate 2852) includes a second sidewall (e.g., the sidewall 2710) of the shared trench, the first sidewall (e.g., the sidewall 2712) being opposite the second sidewall (e.g., the sidewall 2710) in the shared trench 2402.

The method of claim 1, wherein the first VFET and the second VFET are complementary. For example, one is an NFET and the other is a PFET. The first sidewall (shared by the shared trench 2402) is formed as part of the first gate to control a first current of the first VFET, and the second sidewall (shared by the shared trench 2402) is formed as part of the second gate to control a second current of the second VFET. The shared trench 2402 is formed to contain an analyte 2950. The first VFET and the second VFET have threshold voltage shifts in opposite directions according to a charge of the shared trench 2402.

A first current of the first VFET and a second current of the second VFET each have a magnitude that moves in opposite directions according to a charge of the shared trench. A first voltage of the first VFET and a second voltage of the second VFET each have a magnitude that moves in opposite directions according to a charge of the shared trench. The shared trench is a cavity. The shared trench separates a first vertical channel (e.g., vertical channel 812) of the first VFET and a second vertical channel of the second VFET.

According to one or more embodiments, a computer-implemented method of operating a dual gate biosensor (e.g., IC 100) includes holding an analyte 2950 in a shared trench 2402 between an n-type vertical field-effect transistor (VFET) and a p-type VFET, simultaneously measuring (e.g., by one or more measurement devices for voltage, current, capacitance, etc., (not shown)) a first electrical response of the n-type VFET and a second electrical response of the p-type VFET, and determining (e.g., by a computer having a processor and executable instructions in memory executed by the processor, where the computer receives the first and second electrical responses from the measurement devices) a characteristic of the analyte 2950 according to the first and second electrical responses. The computer (not shown) can determine the characteristic of the analyte 2950 based on comparing the first and second electrical responses to numerous stored electrical responses in a database and finding matches to the first and second electrical responses in the database.

Determining the characteristic of the analyte according to the first and second electrical responses comprises determining (e.g., based on the comparison to the stored electrical responses in the database) the presence of the analyte, a concentration of the analyte, and/or both the presence and the concentration of the analyte.

Various embodiments of the present invention are described herein with reference to the related drawings. Alternative embodiments can be devised without departing from the scope of this invention. Although various connections and positional relationships (e.g., over, below, adjacent, etc.) are set forth between elements in the following description and in the drawings, persons skilled in the art will recognize that many of the positional relationships described herein are orientation-independent when the described functionality is maintained even though the orientation is changed. These connections and/or positional relationships, unless specified otherwise, can be direct or indirect, and the present invention is not intended to be limiting in this respect. Accordingly, a coupling of entities can refer to either a direct or an indirect coupling, and a positional relationship between entities can be a direct or indirect positional relationship. As an example of an indirect positional relationship, references in the present description to forming layer “A” over layer “B” include situations in which one or more intermediate layers (e.g., layer “C”) is between layer “A” and layer “B” as long as the relevant characteristics and functionalities of layer “A” and layer “B” are not substantially changed by the intermediate layer(s).

The phrase “selective to,” such as, for example, “a first element selective to a second element,” means that the first element can be etched and the second element can act as an etch stop.

As used herein, “p-type” refers to the addition of impurities to an intrinsic semiconductor that creates deficiencies of valence electrons. In a silicon-containing substrate, examples of p-type dopants, i.e., impurities, include but are not limited to: boron, aluminum, gallium and indium.

As used herein, “n-type” refers to the addition of impurities that contributes free electrons to an intrinsic semiconductor. In a silicon containing substrate examples of n-type dopants, i.e., impurities, include but are not limited to antimony, arsenic and phosphorous.

As previously noted herein, for the sake of brevity, conventional techniques related to semiconductor device and integrated circuit (IC) fabrication may or may not be described in detail herein. By way of background, however, a more general description of the semiconductor device fabrication processes that can be utilized in implementing one or more embodiments of the present invention will now be provided. Although specific fabrication operations used in implementing one or more embodiments of the present invention can be individually known, the described combination of operations and/or resulting structures of the present invention are unique. Thus, the unique combination of the operations described in connection with the fabrication of a semiconductor device according to the present invention utilize a variety of individually known physical and chemical processes performed on a semiconductor (e.g., silicon) substrate, some of which are described in the immediately following paragraphs.

In general, the various processes used to form a micro-chip that will be packaged into an IC fall into four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE) and more recently, atomic layer deposition (ALD) among others. Removal/etching is any process that removes material from the wafer. Examples include etch processes (either wet or dry), and chemical-mechanical planarization (CMP), and the like. Semiconductor doping is the modification of electrical properties by doping, for example, transistor sources and drains, generally by diffusion and/or by ion implantation. These doping processes are followed by furnace annealing or by rapid thermal annealing (RTA). Annealing serves to activate the implanted dopants. Films of both conductors (e.g., poly-silicon, aluminum, copper, etc.) and insulators (e.g., various forms of silicon dioxide, silicon nitride, etc.) are used to connect and isolate transistors and their components. Selective doping of various regions of the semiconductor substrate allows the conductivity of the substrate to be changed with the application of voltage. By creating structures of these various components, millions of transistors can be built and wired together to form the complex circuitry of a modern microelectronic device.

As noted above, atomic layer etching processes can be used in the present invention for via residue removal, such as can be caused by via misalignment. The atomic layer etch process provide precise etching of metals using a plasma-based approach or an electrochemical approach. The atomic layer etching processes are generally defined by two well-defined, sequential, self-limiting reaction steps that can be independently controlled. The process generally includes passivation followed selective removal of the passivation layer and can be used to remove thin metal layers on the order of nanometers. An exemplary plasma-based approach generally includes a two-step process that generally includes exposing a metal such a copper to chlorine and hydrogen plasmas at low temperature (below 20° C.). This process generates a volatile etch product that minimizes surface contamination. In another example, cyclic exposure to an oxidant and hexafluoroacetylacetone (Hhfac) at an elevated temperature such as at 275° C. can be used to selectively etch a metal such as copper. An exemplary electrochemical approach also can include two steps. A first step includes surface-limited sulfidization of the metal such as copper to form a metal sulfide, e.g., Cu₂S, followed by selective wet etching of the metal sulfide, e.g., etching of Cu₂S in HCl. Atomic layer etching is relatively recent technology and optimization for a specific metal is well within the skill of those in the art. The reactions at the surface provide high selectivity and minimal or no attack of exposed dielectric surfaces.

Semiconductor lithography is the formation of three-dimensional relief images or patterns on the semiconductor substrate for subsequent transfer of the pattern to the substrate. In semiconductor lithography, the patterns are formed by a light sensitive polymer called a photoresist. To build the complex structures that make up a transistor and the many wires that connect the millions of transistors of a circuit, lithography and etch pattern transfer steps are repeated multiple times. Each pattern being printed on the wafer is aligned to the previously formed patterns and slowly the conductors, insulators and selectively doped regions are built up to form the final device.

The photoresist can be formed using conventional deposition techniques such chemical vapor deposition, plasma vapor deposition, sputtering, dip coating, spin-on coating, brushing, spraying and other like deposition techniques can be employed. Following formation of the photoresist, the photoresist is exposed to a desired pattern of radiation such as X-ray radiation, extreme ultraviolet (EUV) radiation, electron beam radiation or the like. Next, the exposed photoresist is developed utilizing a conventional resist development process.

After the development step, the etching step can be performed to transfer the pattern from the patterned photoresist into the interlayer dielectric. The etching step used in forming the at least one opening can include a dry etching process (including, for example, reactive ion etching, ion beam etching, plasma etching or laser ablation), a wet chemical etching process or any combination thereof.

For the sake of brevity, conventional techniques related to making and using aspects of the invention may or may not be described in detail herein. In particular, various aspects of computing systems and specific computer programs to implement the various technical features described herein are well known. Accordingly, in the interest of brevity, many conventional implementation details are only mentioned briefly herein or are omitted entirely without providing the well-known system and/or process details.

In some embodiments, various functions or acts can take place at a given location and/or in connection with the operation of one or more apparatuses or systems. In some embodiments, a portion of a given function or act can be performed at a first device or location, and the remainder of the function or act can be performed at one or more additional devices or locations.

The terminology used herein is for the purpose of describing particular embodiments only and is not intended to be limiting. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, element components, and/or groups thereof.

The corresponding structures, materials, acts, and equivalents of all means or step plus function elements in the claims below are intended to include any structure, material, or act for performing the function in combination with other claimed elements as specifically claimed. The present disclosure has been presented for purposes of illustration and description, but is not intended to be exhaustive or limited to the form disclosed. Many modifications and variations will be apparent to those of ordinary skill in the art without departing from the scope and spirit of the disclosure. The embodiments were chosen and described in order to best explain the principles of the disclosure and the practical application, and to enable others of ordinary skill in the art to understand the disclosure for various embodiments with various modifications as are suited to the particular use contemplated.

The diagrams depicted herein are illustrative. There can be many variations to the diagram or the steps (or operations) described therein without departing from the spirit of the disclosure. For instance, the actions can be performed in a differing order or actions can be added, deleted or modified. Also, the term “coupled” describes having a signal path between two elements and does not imply a direct connection between the elements with no intervening elements/connections therebetween. All of these variations are considered a part of the present disclosure.

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

Additionally, the term “exemplary” is used herein to mean “serving as an example, instance or illustration.” Any embodiment or design described herein as “exemplary” is not necessarily to be construed as preferred or advantageous over other embodiments or designs. The terms “at least one” and “one or more” are understood to include any integer number greater than or equal to one, i.e. one, two, three, four, etc. The terms “a plurality” are understood to include any integer number greater than or equal to two, i.e., two, three, four, five, etc. The term “connection” can include both an indirect “connection” and a direct “connection.”

The terms “about,” “substantially,” “approximately,” and variations thereof, are intended to include the degree of error associated with measurement of the particular quantity based upon the equipment available at the time of filing the application. For example, “about” can include a range of ±8% or 5%, or 2% of a given value.

The present invention may be a system, a method, and/or a computer program product at any possible technical detail level of integration. The computer program product may include a computer readable storage medium (or media) having computer readable program instructions thereon for causing a processor to carry out aspects of the present invention.

The computer readable storage medium can be a tangible device that can retain and store instructions for use by an instruction execution device. The computer readable storage medium may be, for example, but is not limited to, an electronic storage device, a magnetic storage device, an optical storage device, an electromagnetic storage device, a semiconductor storage device, or any suitable combination of the foregoing. A non-exhaustive list of more specific examples of the computer readable storage medium includes the following: a portable computer diskette, a hard disk, a random access memory (RAM), a read-only memory (ROM), an erasable programmable read-only memory (EPROM or Flash memory), a static random access memory (SRAM), a portable compact disc read-only memory (CD-ROM), a digital versatile disk (DVD), a memory stick, a floppy disk, a mechanically encoded device such as punch-cards or raised structures in a groove having instructions recorded thereon, and any suitable combination of the foregoing. A computer readable storage medium, as used herein, is not to be construed as being transitory signals per se, such as radio waves or other freely propagating electromagnetic waves, electromagnetic waves propagating through a waveguide or other transmission media (e.g., light pulses passing through a fiber-optic cable), or electrical signals transmitted through a wire.

Computer readable program instructions described herein can be downloaded to respective computing/processing devices from a computer readable storage medium or to an external computer or external storage device via a network, for example, the Internet, a local area network, a wide area network and/or a wireless network. The network may comprise copper transmission cables, optical transmission fibers, wireless transmission, routers, firewalls, switches, gateway computers and/or edge servers. A network adapter card or network interface in each computing/processing device receives computer readable program instructions from the network and forwards the computer readable program instructions for storage in a computer readable storage medium within the respective computing/processing device.

Computer readable program instructions for carrying out operations of the present invention may be assembler instructions, instruction-set-architecture (ISA) instructions, machine instructions, machine dependent instructions, microcode, firmware instructions, state-setting data, configuration data for integrated circuitry, or either source code or object code written in any combination of one or more programming languages, including an object oriented programming language such as Smalltalk, C++, or the like, and procedural programming languages, such as the “C” programming language or similar programming languages. The computer readable program instructions may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider). In some embodiments, electronic circuitry including, for example, programmable logic circuitry, field-programmable gate arrays (FPGA), or programmable logic arrays (PLA) may execute the computer readable program instruction by utilizing state information of the computer readable program instructions to personalize the electronic circuitry, in order to perform aspects of the present invention.

Aspects of the present invention are described herein with reference to flowchart illustrations and/or block diagrams of methods, apparatus (systems), and computer program products according to embodiments of the invention. It will be understood that each block of the flowchart illustrations and/or block diagrams, and combinations of blocks in the flowchart illustrations and/or block diagrams, can be implemented by computer readable program instructions.

These computer readable program instructions may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks. These computer readable program instructions may also be stored in a computer readable storage medium that can direct a computer, a programmable data processing apparatus, and/or other devices to function in a particular manner, such that the computer readable storage medium having instructions stored therein comprises an article of manufacture including instructions which implement aspects of the function/act specified in the flowchart and/or block diagram block or blocks.

The computer readable program instructions may also be loaded onto a computer, other programmable data processing apparatus, or other device to cause a series of operational steps to be performed on the computer, other programmable apparatus or other device to produce a computer implemented process, such that the instructions which execute on the computer, other programmable apparatus, or other device implement the functions/acts specified in the flowchart and/or block diagram block or blocks.

The flowchart and block diagrams in the Figures illustrate the architecture, functionality, and operation of possible implementations of systems, methods, and computer program products according to various embodiments of the present invention. In this regard, each block in the flowchart or block diagrams may represent a module, segment, or portion of instructions, which comprises one or more executable instructions for implementing the specified logical function(s). In some alternative implementations, the functions noted in the blocks may occur out of the order noted in the Figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

The descriptions of the various embodiments of the present invention have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments described herein.

What is claimed is:

1. A method comprising:
forming a first vertical field-effect transistor (VFET) having a first gate; and
forming a second VFET having a second gate, the first and second gates comprising a shared trench formed in between the first VFET and the second VFET, wherein the first gate includes a first sidewall of the shared trench, wherein the second gate includes a second sidewall of the shared trench, the first sidewall being opposite the second sidewall in the shared trench.

2. The method of claim 1, wherein the first VFET and the second VFET are complementary.

3. The method of claim 1, wherein:
the first sidewall is formed as part of the first gate to control a first current of the first VFET; and
the second sidewall is formed as part of the second gate to control a second current of the second VFET.

4. The method of claim 1, wherein the shared trench is formed to contain an analyte.

5. The method of claim 1, wherein the first VFET and the second VFET have threshold voltage shifts in opposite directions according to a charge of the shared trench.

6. The method of claim 1, wherein a first current of the first VFET and a second current of the second VFET each have a magnitude that moves in opposite directions according to a charge of the shared trench.

7. The method of claim 1, wherein a first voltage of the first VFET and a second voltage of the second VFET each have a magnitude that moves in opposite directions according to a charge of the shared trench.

8. The method of claim 1, wherein the shared trench is a cavity.

9. The method of claim 1, wherein the shared trench separates a first vertical channel of the first VFET and a second vertical channel of the second VFET.

10. A semiconductor device comprising:
a first vertical field-effect transistor (VFET) having a first gate; and
a second VFET having a second gate, the first and second gates comprising a shared trench formed in between the first VFET and the second VFET, wherein the first gate includes a first sidewall of the shared trench, wherein the second gate includes a second sidewall of the shared trench, the first sidewall being opposite the second sidewall in the shared trench.

11. The semiconductor device of claim 10, wherein the first VFET and the second VFET are complementary.

12. The semiconductor device of claim 10, wherein:
the first sidewall is formed as part of the first gate to control a first current of the first VFET; and
the second sidewall is formed as part of the second gate to control a second current of the second VFET.

13. The semiconductor device of claim 10, wherein the shared trench is formed to contain an analyte.

14. The semiconductor device of claim 10, wherein the first VFET and the second VFET have threshold voltage shifts in opposite directions according to a charge of the shared trench.

15. The semiconductor device of claim 10, wherein a first current of the first VFET and a second current of the second VFET each have a magnitude that moves in opposite directions according to a charge of the shared trench.

16. The semiconductor device of claim 10, wherein a first voltage of the first VFET and a second voltage of the second VFET each have a magnitude that moves in opposite directions according to a charge of the shared trench.

17. The semiconductor device of claim 10, wherein the shared trench is a cavity.

18. The semiconductor device of claim 10, wherein the shared trench separates a first vertical channel of the first VFET and a second vertical channel of the second VFET.

19. A method comprising:
holding an analyte in a shared trench between an n-type vertical field-effect transistor (VFET) and a p-type VFET;
simultaneously measuring a first electrical response of the n-type VFET and a second electrical response of the p-type VFET; and
determining a characteristic of the analyte according to the first and second electrical responses.

20. The method of claim 19, wherein determining the characteristic of the analyte according to the first and second electrical responses comprises determining a presence of the analyte, a concentration of the analyte, or both the presence and the concentration of the analyte.
